(19) United States
(12) Patent Application Publication
(10) Pub. No.: US 2026/0064902 A1
(43) Pub. Date: Mar. 5, 2026

(54) Generative Artificial Intelligence System and Method of Operating the same

(71) Applicant: Incucomm, Inc., Addison, TX (US)

(72) Inventors: Randal ALLEN, Orlando, FL (US); Eric HANEY, Dallas, TX (US); Russell Shayne WENZEL, Parker, CO (US)

(73) Assignee: Incucomm, Inc., Addison, TX (US)

(21) Appl. No.: 18/773,333

(22) Filed: Jul. 15, 2024

Related U.S. Application Data
(60) Provisional application No. 63/513,555, filed on Jul. 13, 2023.
(60) Provisional application No. 63/514,648, filed on Jul. 20, 2023.
(60) Provisional application No. 63/514,618, filed on Jul. 20, 2023.
(60) Provisional application No. 63/516,718, filed on Jul. 31, 2023.

(51) Int. Cl. G06F 30/15; G06F 30/27

(52) U.S. Cl. CPC G06F 30/15; G06F 30/27

(57) ABSTRACT

A generative artificial intelligence system and method of operating the same to control complex systems. In one embodiment, the method includes incorporating measures of merit into system requirements for an aerospace vehicle system to provide aggregated system requirements and measures of merit, and receiving design parameters of the aerospace vehicle system represented as stochastic variables. The method also includes executing first order physics-based engineering equations of the design parameters with the generative artificial intelligence system on the processor to produce a design for an operation of the aerospace vehicle system to meet the aggregated system requirements and measures of merit in a single iteration improving computational efficiency and reducing power consumption of the processor operating the generative artificial intelligence system.

### CROSS-REFERENCE TO RELATED APPLICATION

This application claims the benefit of U.S. Provisional Patent Application No. 63/513,555, entitled “First-order Artificial Intelligent Designer (FAID),” filed Jul. 13, 2023, U.S. Provisional Patent Application No. 63/514,618, entitled “Generative AI for Complex Systems,” filed Jul. 20, 2023, U.S. Provisional Patent Application No. 63/514,648, entitled “Generative AI for Complex Systems and Systems of Systems,” filed Jul. 20, 2023, and U.S. Provisional Patent Application No. 63/516,718, entitled “First-order Artificial Intelligent Threat Analysis (FAITA),” filed Jul. 31, 2023, which are incorporated herein by reference.

This application is related to U.S. patent application Ser. No. 16/947,535 entitled “Operations and Maintenance System and Method Employing Digital Twins,” filed Aug. 5, 2020, U.S. patent application Ser. No. 18/050,661 entitled “System and Method for Adaptive Optimization,” filed Oct. 28, 2022, U.S. patent application Ser. No. 16/674,942 entitled “System and Method for Constructing a Mathematical Model of a System in an Artificial Intelligence Environment,” filed Nov. 5, 2019, U.S. patent application Ser. No. 18/187,860 entitled “System and Method for State Estimation in a Noisy Machine-Learning Environment,” filed Mar. 22, 2023, U.S. patent application Ser. No. 16/675,000 entitled “System and Method for Vigorous Artificial Intelligence,” filed Nov. 5, 2019, U.S. Provisional Patent Application No. 63/377,278 entitled “An Improved Method for Unsupervised, Noisy-Data Stream Clustering,” filed Sep. 27, 2022 converted to U.S. patent application Ser. No. 18/475,963 entitled “System and Method for Real-Time Data Categorization,” filed Sep. 27, 2023, and U.S. patent application Ser. No. 18/449,532 entitled “Systems and Methods for use in Operations and Maintenance Systems for Controlling the Operation of a Second System,” filed Aug. 14, 2023, which are incorporated herein by reference.

### RELATED REFERENCES

Each of the cited references are incorporated herein by reference.

### Nonpatent Literature Documents

Ashley, H., “Engineering Analysis of Flight Vehicles,” Dover Publications, Mineola, NY, 1974.
Bertin, J., “Hypersonic Aerothermodynamics,” AIAA Education Series, Reston, VA, 1994.
Bowcutt, K., “Building a Career on Tackling the Challenges of Hypersonic Flight,” AIAA, 14 Dec. 2022.
Fleeman, E., Tactical Missile Design, AIAA Education Series, Reston, VA, 2001.
Fleeman, E., “Missile Design and System Engineering,” AIAA Education Series, Reston, VA, 2012.
Heiser, W., Pratt, D., “Hypersonic Airbreathing Propulsion,” AIAA Education Series, Reston, VA, 1994.
Allen, R., “Adaptive Nonconvex Optimization for AI and Machine Learning,” I/ITSEC paper 19109, 2019.
Allen, R., “Evolved AI-Interpretable Network Architectures for Machine Learning,” I/ITSEC paper 19149, 2019.
Allen, R., “Evolved Artificial Intelligence for Stochastic Clustering Unsupervised Learning,” I/ITSEC paper 20258, 2020.
Allen, R., Engel, Z., Haney, E., “Evolved AI for Model-Based Reinforcement Learning,” I/ITSEC paper 21199, 2021.
Allen, R., Engel, Z., Volpi, M., Evolved AI for the Neural Net Enthusiast, I/ITSEC Workshop ID9, 2021.
Norris, G., “Special Topic Hypersonics,” Aviation Week & Space Technology, 2022.
Sayler, K., “Hypersonic Weapons: Background and Issues for Congress,” Congressional Research Service, https://sgp.fas.org/crs/weapons/R45811.pdf, 2023.
Spears, S., Allen, R., Fleeman, E., “First-Order Conceptual Design for Turbojet Missiles and Guided Bombs,” AIAA SciTech Conference, San Diego, CA, 3-7 Jan. 2022, AIAA-2022-0321, 2022.
Waltz, E. and Buede, D., “Data Fusion and Decision Support for Command and Control,” IEEE Trans. Systems, November-December 1986, pp. 865-879.
Thomopolous, S. et al., “Optimal Decision Fusion in Multiple Sensor Systems,” IEEE Trans. AES, September 1987, pp. 644-653.
Skolnik, M., “Radar Handbook,” McGraw Hill, 2008.
Skolnik, M., “Introduction to Radar Systems,” McGraw Hill, 2019.
Hovanessian, H., “Introduction to Sensor Systems,” Artech House, 1988.
Wolfe, W. and Zississ, G., “The Infrared Handbook,” Environmental Research Institute of Michigan, 1993.
Vallado, D. A. “Fundamentals of Astrodynamics and Applications”, 3rd Edition, Microcosm Press, CA and Springer, NY, 2007.
Prussing, J. E. and Conway, B. A. “Orbital Mechanics”, Oxford University Press, 1993.
Zakirov, V. and Sweeting, M., “Specifics of Small Satellite Propulsion: Part 1”, 15^{th} AIAA/USU Conference on Small Satellites, SSC01-XI-6.
https://www.defensenews.com/naval/2023/01/05/russias-hypersonic-missile-armed-ship-to-patrol-global-seas/.
https://en.wikipedia.org/wiki/3M22_Zircon.
https://en.wikipedia.org/wiki/M982_Excalibur.

### TECHNICAL FIELD

The present disclosure is directed, in general, to artificial intelligence systems and, more specifically, to a generative artificial intelligence system and method of operating the same to control complex systems.

### BACKGROUND

Complex systems such as supply chain management, manufacturing operations, training operations, acquisition, test and integration processes, military operations, and intelligence gathering, among others, employ a large number of subsystems that need to be designed and controlled. Each subsystem should be properly assessed with an understanding toward the impact on the system as a whole. Although common themes, approaches, and technologies are involved, the limited user audience means the complex system is never consolidated. These problems are solved by their own communities. Traditional conceptual design would benefit from rapid, holistic, and optimized assessment of the complex systems.

### SUMMARY

Deficiencies of the prior art are generally solved or avoided, and technical advantages are generally achieved, by advantageous embodiments of the present disclosure of a generative artificial intelligence system and method of operating the same to control complex systems. In one embodiment, the method includes incorporating measures of merit into system requirements for an aerospace vehicle system to provide aggregated system requirements and measures of merit, and receiving design parameters of the aerospace vehicle system represented as stochastic variables. The method also includes executing first order physics-based engineering equations of the design parameters with the generative artificial intelligence system on the processor to produce a design for an operation of the aerospace vehicle system to meet the aggregated system requirements and measures of merit in a single iteration improving computational efficiency and reducing power consumption of the processor operating the generative artificial intelligence system.

The foregoing has outlined rather broadly the features and technical advantages of the present disclosure in order that the detailed description of the disclosure that follows may be better understood. Additional features and advantages of the disclosure will be described hereinafter, which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, reference is now made to the following detailed description taken in conjunction with the accompanying drawings, in which:

FIG. 1 illustrates is a block diagram of an embodiment of a generative artificial intelligence (“AI”) system;

FIGS. 2 to 4 illustrate graphical representations demonstrating examples using a generative AI system;

FIG. 5 illustrates a block diagram demonstrating an example using a generative AI system;

FIGS. 6 to 9 illustrate flow charts of methods to develop a design of a system;

FIG. 10 illustrates a perspective view of an embodiment of an aerospace vehicle system demonstrating the application of a generative AI system;

FIG. 11 illustrates a flow chart of a method or process to determine a threat analysis;

FIG. 12 illustrates a perspective view of an embodiment of an aerospace vehicle system demonstrating the application of a generative AI system;

FIGS. 13 and 14 illustrate tornado charts demonstrating sensitivities and variance of inputs into a generative AI model created by a generative AI system for the aerospace vehicle of FIG. 12;

FIG. 15 illustrates a perspective view of an embodiment of an aerospace vehicle system demonstrating the application of a generative AI system;

FIGS. 16 to 18 illustrate tornado charts employing the Breguet equation within a generative AI model that demonstrate uncertainties to the design created by the generative AI system;

FIG. 19 illustrates a flow chart of a method to develop a design of a system;

FIGS. 20 to 22 illustrates tornado charts of implementations of the physical equations representing sensor systems;

FIG. 23 illustrates a flow chart of a method to develop a design of a system; and

FIG. 24 illustrates a block diagram of an embodiment of an apparatus for operating a generative AI system.

Corresponding numerals and symbols in the different figures generally refer to corresponding parts unless otherwise indicated and, in the interest of brevity, may not be described after the first instance.

### DETAILED DESCRIPTION

The design of complex systems such as aircraft or spacecraft systems is an inherently coupled, multidisciplinary process. The design typically follows a flow of conceptual-preliminary-detailed design phases where each series involves a higher level of understanding of the vehicle system and a higher fidelity of representation of the system (i.e., more complex modeling, more data required, higher computational requirements). Conceptual design has not been solved holistically. Instead, it is very often created as a bespoke solution for a subset of vehicle types such as helicopter, subsonic fixed wing, and cubesat.

Optimal system design is desired, but is often only solved by inference or with extensive setup. Also, it is not typically included until the preliminary or detailed design phase. Common approaches to optimization involve continuous functional relationships and/or explicit functions to be known a priori, which eliminates the capability to include optimal design when knowledge of the system is uncertain or objective functions are nonconvex, discontinuous, nondifferentiable.

There exists a substantial amount of use cases beyond traditional conceptual design that would benefit from rapid, holistic, and optimized assessment of vehicle systems or threat analysis such as business case assessment, competitive intelligence, threat assessment, and reverse engineering. It would be beneficial to the system for first-order artificially intelligent system design such as, without limitation, vehicle design or threat analysis that incorporates holistic system design impacts paired with a nonconvex, discontinuous, nondifferentiable optimization capability. Such a system would provide stakeholders beyond the vehicle design or threat analysis community to be able to rapidly assess the feasibility and capability of vehicle or threat analysis systems.

Conventional designs are unable (in practical terms) to autogenerate an entire new first-order aerospace vehicle or threat analysis design. With a high-performance non-linear optimization system, and the entire corpus of flight dynamical equations, along with expert system design rules, a hybrid artificial intelligence (“AI”) system is described herein. Among the teachings are the incorporation of discontinuous, non-convex, and non-differentiable system concepts and equations, heretofore unfeasible on practical computing platforms. The benefits of the systems described by this disclosure include faster, more secure creation of new designs, and faster, more secure assessments of systems observed for analysis purposes. In other words, this generative AI system can autonomously generate designs, can generate assessments of observed designs, or generate potential threat capabilities, and control systems in real-time.

Generative artificial intelligence is an emerging subset of AI and machine learning (“ML”). Generative AI is defined as a system that creates new content having learned from a corpus of training data. When prompted with a probing question, the generative AI interpolates from its existing knowledge to generate the best response. The created design may be a refinement of an existing solution if the prompting question is standard, however unique solutions may be created if the prompting question uniquely combines requirements and assumptions in a non-standard manner. The underlying techniques for most generative AI systems include neural networks. The neural networks teach efficient approaches to handle very large training sets and/or their capability to ingest questions and egest responses in more intuitive formats such as natural language, software code, and images, among others.

Neural networks typically have limitations such as linearity, continuity, differentiability, incompatibility with sparse and uncertain datasets, and inexplicability or un-explainability, among others. For generative AI applications where neural networks and other mainstream AI methods are limited or not a proper technique, other approaches should be utilized.

There exists a set of use cases where existing generative AI solutions are not sufficient such as those systems with little or no training data due to lack of data infrastructure, training data is restricted due to information security concerns, newness of the underlying system has not allowed for sufficient data to be captured, the underlying systems are governed by bespoke or niche rules that are not broadly understood nor captured in datasets, or the systems contain significant noise and uncertainty in the data or operations. Uses cases with these or other similarly limited restrictions are poorly suited to conventional general-purpose generative AI, however they would equally (or even more so) benefit from generative AI solution disclosed herein. These unserved use cases include, but are not limited to, supply chain management, manufacturing operations, training operations, acquisition, test and integration processes, military operations, and intelligence gathering.

A systemic approach to the creation and implementation of generative AI systems within targeted domains would be beneficial. This is achieved by utilizing existing knowledge of the underlying system/process to create a defined mathematical representation (a plant model) and then enabling the generative probing of the solution space to output the optimal system/process given any combination of requirements, assumptions, or desired business outcome.

Conventional systems are unable (in practical terms) to autogenerate a system or process of high complexity-interdependency, and uncertainty. A hybrid generative AI system is described in this disclosure with a high-performance non-linear optimization system, and embedded teaching of the domain, along with expert system design rules. Among the improvements are the incorporation of discontinuous, non-convex, and non-differentiable system equations, heretofore unfeasible on practical computing platforms.

The benefits of the systems described herein provide faster, more secure creation of new designs, and faster, more secure assessments of systems observed for analysis. In other words, this generative AI system can autonomously generate designs, or can generate assessments of observed designs, and control systems and processes based on the assessments. Benefits also include the removal of human subjectivity in design assessment and control of complex systems, imparting of biases, and the inherent limitation of human-in-the-loop time to generate new concepts.

Improved evolved AI methods that include less training data, explicitly address non-linearity and discontinuities, operate with uncertain data, and provide transparent explainability are disclosed in U.S. patent application Ser. Nos. 18/050,661 and 16/674,942. Generative AI is one such embodiment of evolved AI extending the capabilities to generate completely new systems or processes. Existing knowledge of the system or process is comprehended by the evolved AI solution and establishes a baseline of training/calibration. The generative AI disclosed herein then allows the creative probing of the solution to generate unique systems or processes that are unobvious to the user and/or would require extensive analysis to arrive at manually, if possible.

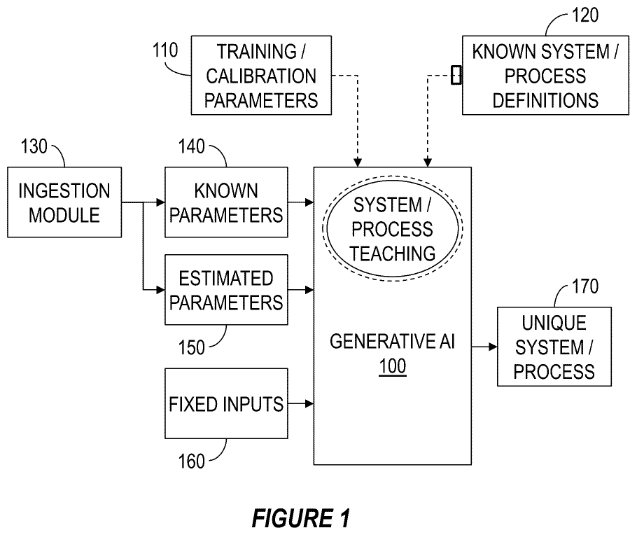

FIG. 1 illustrates a block diagram of an embodiment of a generative AI system 100. The generative AI system 100 (also including/incorporating, without limitation, a generative first-order artificial intelligence designer (“FAID”) system and a generative first-order artificial intelligence threat analysis (“FAITA”) system) is operable on a processor and memory that can create models and processes to design, control, operate and maintain complex real systems such as vehicle systems (e.g., aerospace vehicle systems) and threat analysis systems to improve the design, monitoring, operation and maintenance thereof. While the disclosure provides examples for generative AI for aerospace vehicle systems, threat analysis systems and sensor systems, the concepts herein apply generally to other complex real systems such as, without limitation, radars and electronic warfare systems, and processes such as, without limitation, training programs and acquisition programs. Any of the embodiments of the generative AI systems disclosed herein are also operable on a processor and memory to perform the design, control, operate and maintain complex real systems.

The use of known teaching information such as training and calibration parameters 110 shapes the relationships of a generative AI model by the generative AI system 100. This may include known business rules, accounting principles, engineering principles, physical laws, regulations, statutes, rules of engagement, or many other understood functions governing the system or process. These relationships may be shaped by empirical, historical, or experimental data where available, or may include theoretical or stochastic inputs or parameters where data is not available. The generative AI system 100 trains these relationships on known system/process definitions 120. This process calibrates the solution such that it is able to reliably recall standard designs and realistically interpret within the design space for previously unseen designs.

Once the generative AI system 100 is trained, an ingestion module 130 is created for probing questions. This may include the use of other technologies such as image processing, natural language processing, or large language models. The outcome of this pre-processing is to pass along system/process parameters for the generative AI system 100. These parameters may be exact (known parameters 140) as the probing question makes hard (definitive) assumptions or these parameters may have stochastic uncertainty (estimated parameters 150) if the probing questions contain uncertain language, is unclear about intent, contains contradictory inputs, or has noisy sources of information.

The probing questions may be directly input by end users in instances where there is an elevated level of sophistication in the user-base and the time to make a decision is longer. However, there exists other use cases where the design sophistication of the user/stakeholders is lower and the time to make a decision is much faster. In this case, the probing questions may be automatically generated from sensor data, images, videos, or other data feeds.

Alongside these independent parameter inputs generated from the probing question, there may also be fixed parameters or inputs 160 that describe the design space. These may include technology growth parameters, material constants, environmental conditions, demographics, market assumptions, geopolitical status, sentiment analysis from open-source or close-source intelligence, or other information to depict the holistic design space, but is often left implied from a probing question.

The generative AI model from the generative AI system 100 results in the description of the unique system/process 170. This includes design parameters to understand the capabilities and requirements of the system. The output format may be graphical, numerical, or derive values for a common interface such that downstream assessment/action may take place (e.g., control, operation and maintenance). For instance, generative computer aided design (“CAD”) models may be inputs into vehicle tracking or targeting systems, or description for use in mission planning systems. The desired objective value of a sensor system, or an aerospace vehicle system can be represented by multiple metrics and are context-sensitive to the decision-maker, organization, acquisition process, and previous investments, among others. An objective of the design process is to mathematically optimize this value.

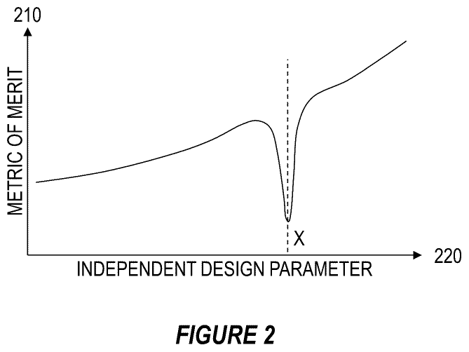

FIG. 2 illustrates a graphical representation demonstrating an example using a generative AI system. The desired objective value of a system can be represented by multiple metrics and are context-sensitive to the decision-maker, among others. The goal of the design process is to mathematically optimize this value. A primary metric of merit (i.e., measure of merit) 210 is the objective function of the process such as cost, net present value, operational readiness, organizational risk, or any other metric (or combination therein) that is important to the viability of the system. In this instance, the desired goal of the analysis system is to find a design that reduces (e.g., minimizes) this metric subject to the assumptions, requirements, and constraints of the process and the given generative prompt. Several independent design variables or parameters may be of interest. While the FIGURE represents a single independent deterministic design variable or parameter 220, the generative AI system may employ multivariate descriptions of systems.

As the number of design parameter(s) increases, the process complexity increases and therefore generally increases the metric of merit 210. At an approximate design value of X, the system incorporates components of an existing design that can be repurposed and therefore reduce the metric of merit 210. For parameter values less than and greater than X, this design does not satisfy performance, financial, and other constraints of the new system. Only within a limited range around X, the metric value decreases (i.e., the objective function is discontinuous around X). Specifying the generative AI system around this design point is optimal but unobvious.

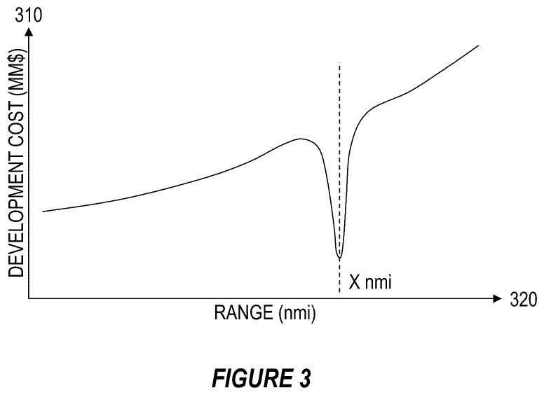

FIG. 3 illustrates a graphical representation demonstrating an example using a generative AI system. The desired objective value of a system can be represented by multiple metrics and are context-sensitive to the decision-maker, among others. The goal of the design process is to mathematically optimize this value. The example is representative of an aerospace vehicle system such as a subsonic commercial aircraft. A primary metric of merit (i.e., measure of merit) is the development cost 310 (cost in millions of dollars (“MM$”) on the y-axis) that is important to the financial viability of the product. The desired goal of the analysis system is to find the design that reduces or minimizes the development cost 310. Several independent design variables are of interest. While vehicle range 320 (in nautical miles (“nmi”)) is depicted on the x-axis as a single independent variable or parameter, the generative AI system may employ multivariate descriptions of vehicle systems.

As the vehicle range increases, the aerospace vehicle system gets larger and more complex. Longer wings require more advanced materials. Larger fuselages require additional structural engineering. All of the above require more powerful engines to maintain expected performance. Therefore, generally, development cost 310 increases with vehicle range 320.

At an approximate vehicle range 320 of X nmi, the aerospace vehicle system incorporates an existing aircraft engine that has already been fielded and certified for operations. For vehicle ranges 320 shorter and greater than X nmi, this aircraft engine does not satisfy performance, financial, and other constraints of the new system. Only within a limited range around X nmi, does the development cost 310 decrease (i.e., the objective function is discontinuous around X nmi). Advancing the aerospace vehicle system around this design point is optimal.

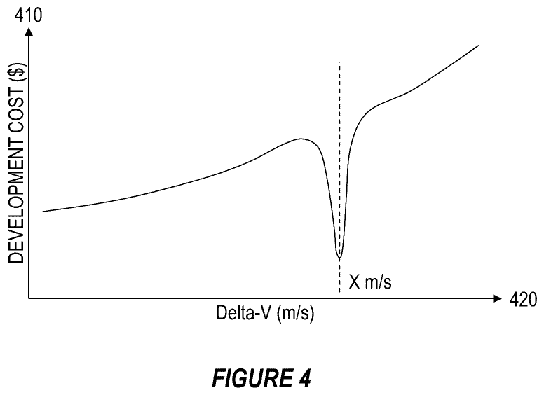

FIG. 4 illustrates a graphical representation demonstrating an example using a generative AI system. Again, the desired objective value of a system can be represented by multiple metrics and are context-sensitive to the decision-maker, among others. The goal of the design process is to mathematically optimize this value. The example is representative of an aerospace vehicle system such as a small satellite (“smallsat”). A primary metric of merit (i.e., measure of merit) is the development cost 410 (cost in dollars (“$”) on the y-axis) that is important to the financial viability of the product. The desired goal of the analysis system is to find the design that reduces or minimizes the development cost 410. Several independent design variables are of interest. While vehicle maximum delta-V 420 (in miles per second (“m/s”)) is depicted on the x-axis as a single independent variable or parameter, the generative AI system may employ multivariate descriptions of vehicle systems.

As the delta-V 420 capability increases, the smallsat system gets larger and more complex. Longer burns require more and perhaps more exotic fuel types. Larger smallsats require additional structural and electrical power for thermal and articulation control. All of the above require greater thrust capabilities to achieve expected performance. Therefore, generally, development cost 410 increases with delta-V 420 capacity.

At an approximate design delta-V 420 of X m/s, the aerospace vehicle system incorporates an existing “off-the-shelf” propulsion system that has already been proven and certified for operations. For delta-Vs 420 shorter and greater than X m/s, this aircraft engine does not satisfy performance, financial, and other constraints of the new system. Only within a limited range around X m/s, does the development cost 410 decrease (i.e., the objective function is discontinuous around X m/s). Advancing the aerospace vehicle system around this design point is optimal.

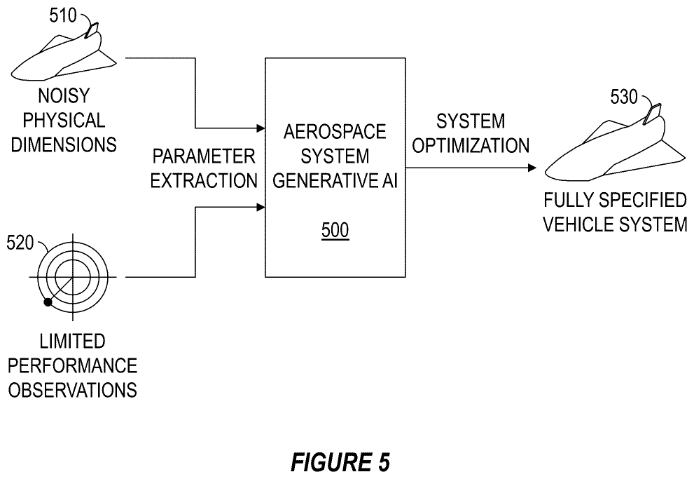

FIG. 5 illustrates a block diagram demonstrating an example using a generative AI system 500. The example is representative of a threat assessment of an aerospace vehicle system such as a hypersonic vehicle or smallsat. This may be of interest for national security, competitive intelligence, or other purposes.

Multiple images of the flight vehicle system are available (noisy physical dimensions 510 received and stored in memory). However, they are from different angles and the details are fuzzy due to the speed, distance, or other characteristics of the vehicle assessment. During parameter extraction, this creates uncertain distributions of physical dimensions such as a bounded range of potential values for overall length, wing sweep angle, engine exhaust area, vehicle size, fuel-to-mass ratio, and propulsion capabilities.

Another observed input is a limited time series of sensor (radar) returns (limited performance observations 520 received and stored in memory). This provides time and location data that can be used to infer speed, acceleration, and altitude. It is unknown where this operation is within the vehicle's flight envelope. Due to this and the limited nature of the data captured, a probabilistic range of values for performance characteristics such as maximum speed, cruising altitude, maximum g-loading of airframe, maximum delta-V, orbital altitude, and detonation/kill-zone pattern is created.

These observed, but uncertain, parameters are provided to the generative AI system 500 (received and stored in memory). They are combined with historical, empirical, and fixed input parameters such as typical fuel properties for hypersonic vehicles or smallsat, drag or aerodynamic coefficients as a function of Mach, altitude, and size, among others.

The generative AI system 500 (executing on a processor) then evaluates this combination of observed and known parameters to fully define the aerospace vehicle system (such as a fully specified vehicle system 530) for system optimization. This is achieved by utilizing the non-linear stochastic optimization module to automatically select the optimal vehicle design given the known fixed parameters. In this case, the generative AI system 500 has been trained on a known corpus of hypersonic vehicle or smallsat systems and can accurately estimate the probable specification of the unknown system.

Thus, the generative AI system builds generative AI models with a comprehensive set of physics-based engineering equations, populates the models with data including uncertainty, and verifies and validates the models with known baseline systems. The generative AI system then implements the system within the context of a complex system of systems to, for instance, control, operate and maintain complex real systems such as vehicle systems (e.g., aerospace vehicle systems) and threat analysis systems to improve the design, monitoring, operation and/or maintenance thereof.

In the context of model-based systems engineering (“MBSE”), the generative AI system incorporates performance and other measures of merit into the system requirements, in aggregate, to optimize the design of, for instance, an aerospace vehicle system. For example, the operation including range, endurance, and service ceiling of an unmanned air system (“UAS”) may all be augmented (even maximized) subject to constraints such as specific fuel consumption, weight, etc. Optimal parameters are reported, including sensitivity analyses, such that the system engineering system can immediately identify the performance drivers. In the context of multidisciplinary design optimization (“MDO”), the generative AI system can be used for the simultaneous design of competing requirements such as airbreathing hypersonic aircraft and missiles that are characterized by strong interdependence between the airframe (aerodynamics) and engine (propulsion).

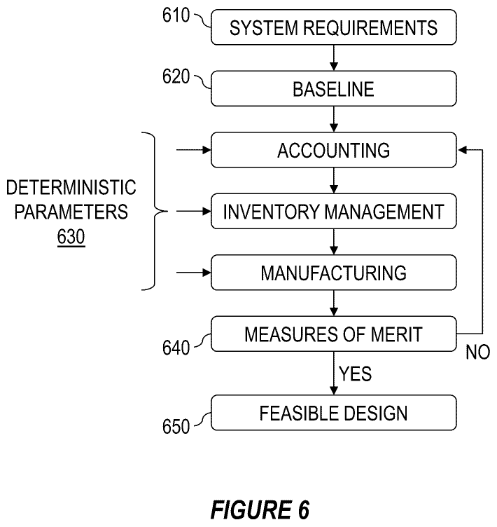

FIG. 6 illustrates a flow chart of a method or process to develop a design of a system. The process begins with system requirements 610 (stored in memory), assumes a baseline 620 (stored in memory), and iteratively determines a feasible design by systematically designing each subsystem of the system (via a processor) with deterministic parameters 630 (stored in memory) such as accounting information, inventory management information, and manufacturing information until measures of merit 640 (e.g., performance requirements stored in memory) are met. Iterations occur because a particular choice of deterministic parameters may lead to a design that does not meet the performance requirements and must be modified. Over time, however, the feasible design 650 converges until measures of merit 640 are met. The relationship between different stakeholders is often loosely coupled or not specified at all. In other words, the impact between manufacturing and financial outcomes may be acknowledged, but the precise relationship is not defined.

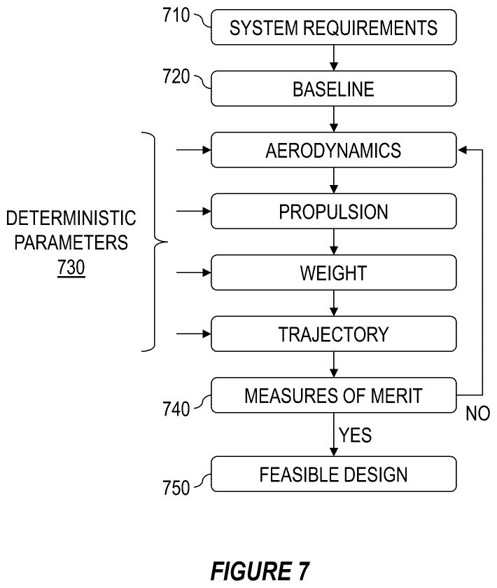

FIG. 7 illustrates a flow chart of a method or process to develop a design of system such as an aerospace vehicle system. The process begins with system requirements 710 (stored in memory), assumes a baseline 720 (stored in memory), and iteratively determines a feasible design by systematically designing each subsystem (via a processor) of the aerospace vehicle or smallsat system with deterministic parameters 730 (stored in memory) such as aerodynamics, propulsion, weight, and trajectory until measures of merit 740 (e.g., performance requirements stored in memory) are met. Iterations occur because a particular choice of deterministic parameters may lead to a design that does not meet the performance requirements and must be modified. Over time, however, the feasible design 750 converges until measures of merit 740 are met. The relationship between different stakeholders is often loosely coupled or not specified at all. In other words, the impact between aerodynamics and trajectory may be acknowledged, but the precise relationship is not defined.

In an embodiment, a plant model of the process may be created but is very often full of hard assumptions, single point deterministic values, and historical placeholders that are obscured from the final design. Data from each domain is stored within its own information system and is not aware of nor integrated into a larger information ecosystem. Connections are made ad hoc, manually, or not at all.

Process design is often made by consensus with some mix of quantitative and qualitative assessment from each stakeholder domain. This entire flow may be integrated in a sophisticated organization with a mature process; however it is very often ad hoc on a process-by-process basis. In either case, the resources and time to perform such a design selection is substantial.

FIG. 8 illustrates a flow chart of a method or process to develop a design of a system such as a commercial operations system. In this case, the generative AI system incorporates the measures of merit (e.g., performance requirements) into the system requirements (aggregated system requirements and measures of merit 810) stored in memory such that they can be met collectively. The measures of merit may include, without limitation, cost, reliability and/or safety of the commercial operations system. Also, the design parameters (e.g., accounting information, inventory management information, and manufacturing information parameters) are provided (received and stored in memory) represented by stochastic (random) variables 820 as recommended by subject matter experts. In this MBSE/MDO embodiment, the generative AI system 830 contains (stored in memory) the first-order physics-based engineering (mathematical) equations (relationships, a plant model) representing the accounting information, inventory management information, manufacturing information parameters, etc. When executed on a processor, the generative AI system 830 produces an advanced (e.g., optimal) design 840 for an operation of the commercial operations system meeting the aggregated system requirements and measures of merit 810 in a single step (or iteration) improving computational efficiency and reducing power consumption and other resources of the processor operating the generative AI system 830. Furthermore, (optimal) design parameters (extracted automatically from the stochastic variables 820) are reported (reported design parameters 850), including sensitivity analyses of the design parameters, such that the system engineer can immediately identify performance drivers for the design 840 to control, operate, and/or maintain (maintenance) the commercial operations system. Of course, a multitude and diversity of domains can be applied to the generative AI system 830 to produce the design 840.

The process of FIG. 8 is described with respect to three primary stakeholders/domains. It should be evident that a multitude and diversity of domains such as design for manufacturing, process management, supply chain, condition-based maintenance, financial, organizational reputation, personnel management, among others, would similarly be integrated into a holistic description of a process plant model.

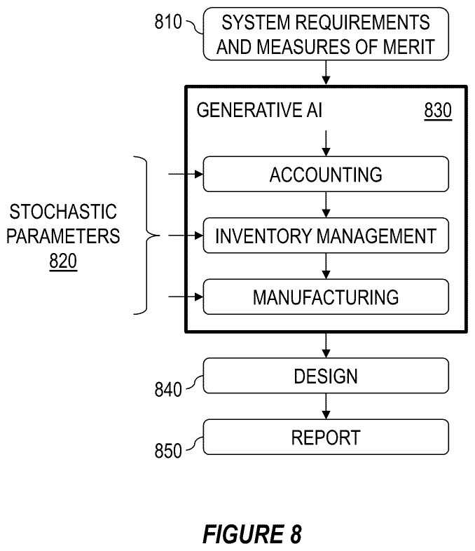

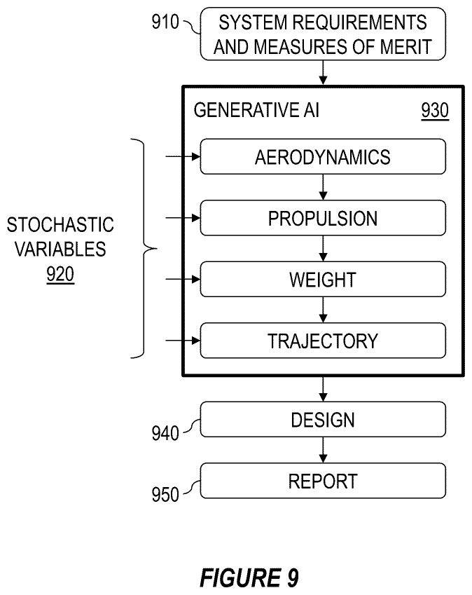

FIG. 9 illustrates a flow chart of a method or process to develop a design of system such as an aerospace vehicle system. In this case, the generative AI system incorporates the measures of merit (e.g., performance requirements) into the system requirements (aggregated system requirements and measures of merit 910) stored in memory such that they can be met collectively. The measures of merit may include, without limitation, survivability, cost, reliability and/or safety of the aerospace vehicle system. As an example, survivability is enhanced with low sensor cross section, high altitude flight, and high speed flight of the aerospace vehicle system. As another example, reliability can be achieved by having few events (e.g., minimal propulsion staging, if any; wing deployment mechanisms; etc.), minimal number of parts, having a short flight time, and a low threat environment depending on the application.

Also, the design parameters (e.g., aerodynamic, propulsion, weight, and trajectory parameters) are provided (received and stored in memory) represented by stochastic (random) variables 920 as recommended by subject matter experts. In this MBSE/MDO embodiment, the generative AI system 930 contains (stored in memory) the first-order physics-based engineering (mathematical) equations (relationships, a plant model) of aerodynamics, propulsion, weight and trajectory parameters, etc. When executed on a processor, the generative AI system 930 produces an advanced (e.g., optimal) design 940 for an operation of the aerospace vehicle system meeting the aggregated system requirements and measures of merit 910 in a single step (or iteration) improving computational efficiency and reducing power consumption and other resources of the processor operating the generative AI system 930 . . . . Furthermore, (optimal) design parameters (extracted automatically from the stochastic variables 920) are reported (reported design parameters 950), including sensitivity analyses of the design parameters, such that the system engineer can immediately identify performance drivers for the design 940 to control, operate, and/or maintain (maintenance) the aerospace vehicle system. Of course, a multitude and diversity of domains can be applied to the generative AI system 930 to produce the design 940.

Again, the design can be implemented within the context of a complex system of systems to, for instance, control, operate and maintain complex real systems such as vehicle systems (e.g., aerospace vehicle systems) and threat analysis systems to improve the design, monitoring, operation and/or maintenance thereof. Additionally, the generative AI system improves the efficiency and reduces power consumption of the processor and memory operating the generative AI system by reducing the iterations of developing the advanced design. The generative AI system 930 builds a model with a comprehensive set of physics-based engineering equations; populates the model with data, including uncertainty, verifies and validates the model with known baseline systems, implements (controls) the system within the context of a complex system of systems.

The improvement in the efficiency and reduction in power consumption of the processor and memory operating the generative AI system can be expressed as set forth below. For example, in aerodynamic solutions, operating the generative AI system does not have to run computational fluid dynamics (“CFD”) models that could take hours or days depending on how much aerodynamic data is needed. Looking at a four hour window (240 minutes or 14400 seconds) and the generative AI system executes in a few seconds (say 10), then the generative AI system is 99.93 percent more efficient. A laptop personal computer (verses server(s) for conventional solutions) operable to execute the generative AI system uses approximately 0.75 amps with 120 volts equaling 90 watts. Energy equals power multiplied by time (time being variable, 14400 seconds verses 10 seconds). So, the energy usage for the generative AI system as disclosed herein is 99.93 percent less than CFD. Compared to ChatGPT's generative AI, ChatGPT's generative AI uses about 363 billion parameters, compared to the generative AI system disclosed herein uses about 264 parameters, which is nine orders-of-magnitude difference. In other words, the generative AI system disclosed herein is at least 90 percent more efficient and nine orders of magnitude difference than conventional designs. The efficiency gain is applicable to all applications including the complex systems specifically disclose herein.

Each of the domains in the processes described herein have been explicitly defined with mathematical relationships including their interdependencies to each other and their overall impact on the measures of merit of the system requirements and measures of merit. In contrast to the conventional systems that dictate single point values of process parameters, the generative AI system accepts stochastic ranges of input (design) parameters. In other words, the input parameters are randomly determined; having a random probability distribution or pattern that may be analyzed statistically but may not be predicted deterministically. This capability is very important when designing future processes that are subject to uncertainty such as the future cost of capital is within a range of values, or the risk of supplier bankruptcy is a likelihood of occurrence. Depending on the generative probe, these parameters may be adjusted or refined to fit the circumstances.

From this stipulated scenario, the generative AI system creates an optimally designed process. This is performed by modulating independent design parameters (in accordance with executing the first-order physics-based engineering equations) until the multi-dimensional combination arrives at a design with the optimal (maximum or minimum) measures of merit of the system requirements and measures of merit. This design may include unobvious design decisions, design points near sharp discontinuities in business value, and/or stochastic ranges of design consideration based on uncertain assumptions.

The generative AI system is applicable to any process or system that can be defined mathematically and has the need for rapid creation of optimal designs. Illustrative use cases are described below, although other use cases are comprehended. Those skilled in the art will appreciate the complexity of these questions and the benefit of creating optimal solutions in a rapid timeframe. It should be noted that each of these described use cases employ high fidelity plant models that are highly non-linear, discontinuous, noisy, and uncertain.

As an example, a manufacturing process may be an important component of the design of a system. Assume a company manufactures medical equipment including, but not limited to, ventilators. A plant model can be created describing the raw material, facilities, equipment, and personnel required to manufacture a certified medical-grade ventilator. This includes the cost and delivery schedule of the finished goods. The plant model is created by utilizing existing control system data, inventory management system data, company accounting standards, Federal Reserve economic forecasts, and World Health Organization risk assessments, as exemplary data sources.

By means of the generative AI system, the plant model is enhanced to create new optimum process designs from a minimal human prompt such as defining the characteristics of a separate manufacturing facility in a separate location with different labor, facility, and energy prices. The generative AI system can create maximum shareholder value over the next five years by balancing the existing booked business, projecting additional inventory to meet a spike in demand from a healthcare emergency, and projecting the facility carrying costs and current/future cost of capital to control the operation of the manufacturing processes.

As an example, supply chain management may be an important component for military operations. An operational military command is responsible for surveillance and control of a geographic region. To perform this mission, they require multiple operational assets to be ready along with qualified, proficient operators. Frequent use of these assets necessitates spare parts, replacement parts, and consumable materials to stay operationally ready. Although operations have a nominal cadence, they are subject to substantially increased activity and/or changes in mission type due to multiple external factors. Manufacture, acceptance, and delivery of this material to the correct location and in the correct quantity is required to meet command readiness goals.

By means of the generative AI system, the plant model of this supply chain is now capable of suggesting designs with optimum readiness for both current and contingent future operations. For example, new intelligence reports have increased the likelihood of increased operations in a specific subregion of the command in the next three months. The generative AI system design prescribes the addition of a new forward operating base due to the new operations, as well as an immediate increase in spare parts requested from the manufacturer with an acute emphasis on sensor systems that will be emphasized in the potential new operations.

As an example, enterprise pipeline training is an important component for any organization. For instance, a plant model can be created for aircrew training for the United States Air Force (“USAF”). The USAF training solution includes a comprehensive representation of air crew training processes, assets, sequencing, and uncertainties. This results in an objective future assessment of the timing, availability, and quality of air crew ready for service. By means of the generative AI system, the USAF plant model can be tasked to autonomously generate optimal management decisions, such as the allocation of instructor pilots, or contractor support plans to achieve bounded goals of the command.

As an example, testing and integration of new assets is an important component for any organization. For instance, a police department may need to acquire new vehicles for its patrol officers. The acquisition includes delivery timelines, payment schedules, and acceptance criteria. As new vehicles are delivered, final customization of the vehicles is done by the department before providing them to the officers. The officers must be trained on the new vehicles before using them in operations, and they must relinquish their existing patrol vehicle once they have been trained. A plant model has been created defining this entire acquisition contract, as well as the ancillary impacts on vehicle maintenance, personnel, and municipal budgeting.

By means of the generative AI system, the plant model is enabled to generate optimal decisions to changes in the contract. For example, the new vehicle provider has stated that due to a labor shortage at a vendor site there will be less than expected vehicle deliveries in December. Another vendor has been identified to supplement the shortage, which will be made up in January. Due to the contract stipulations, the payments with be shifted from one fiscal year to the next. When prompted for an optimum contracting action in order to not require a budget amendment, the generative AI system prescribes moving forward multiple service life extension modifications to existing vehicles and deferment of spare parts for new vehicles. This combination maintains desired patrol capability while having a net zero impact on both the acquisition contract amount and the overall police budget.

FIG. 10 illustrates a perspective view of an embodiment of an aerospace vehicle system 1000 demonstrating the application of a generative AI system. In this example, the aerospace vehicle system 1000 is a M982 Excalibur extended-range guided artillery shell. The aerospace vehicle system 1000 has a mass (M″) of 48 kilograms (“kg”) (106 pounds (“lbs”), a length of 100 centimeters (“cm”) (39.2 inches (“in”), and a diameter of 155 millimeters (“mm”) (6.1 in). Application of the generative AI system's first-order conceptual design optimization, with maximum glide range performance as an MBSE system requirement, achieved a reasonable result of 29 kilometers (“km”) where the M982 Excalibur (variant 1a-1) nominal performance is cited as 23 km. (See https://en.wikipedia.org/wiki/M982_Excalibur, previously incorporated by reference.)

The following aerodynamic parameters were tuned to produce maximum glide range performance in a single step using the generative AI system (also referred to as FAID):
Angle of Arrival (“AoA”)=10.5 degrees (“deg”);
1 Canard Sweep=0.3 deg;
1 Canard Chord=1.5 in;
1 Canard Span=5.4 in
1 Canard NACA 0020
2 Tail Sweep=5.0 deg
2 Tail Chord=1.4 in
2 Tail Span=5.4 in
2 Tail NACA 0020.

Another example of an application for the generative AI system is for component (or subsystem) of an aerospace vehicle system such as a rocket motor. Given the geometry of the rocket motor, propellant properties, and thrust requirements, the generative AI system can determine the required chamber pressure and resulting specific impulse, propellant flow rate, and propellant burn area. Range performance can be determined by assuming optimized aerodynamic properties.

Geometric properties include exit diameter (area), e.g., de=3.78 in, throat diameter (area), e.g., d*=1.52 in, and the exit-to-chamber pressure ratio (“pe/pc”) can be determined using interpolation. The propellant properties include density, e.g., 0.065 pounds mass per cubic inches (“lbm/in³”), characteristic velocity, e.g., 5200 feet per second (“ft/sec”), burn rate at 1000 pounds per square inch (“psi”), e.g., 0.5 inches per second (“in/sec”), burn rate exponent, e.g., 0.3, and discharge efficiency, e.g., 96 percent. Given the desired thrust, the chamber pressure (“pc”) can be computed, wherein pe/pc=0.02491. The desired boost thrust equals 10× the weight, and the desired sustain thrust equals drag at flight conditions.

| | | Chamber | Specific | Mass Flow | Propellant |
|---|---|---|---|---|---|
| | Thrust | Pressure | Impulse | Rate \dot{m} | Burn Area |
| | (lb) | (pc) (psi) | (Isp) (sec) | (lbm/sec) | (A_{b}) (in²) |
| Boost | 5096 | 1764 | 257 | 19.8 | 513 |
| Sustain | 801 | 301 | 239 | 3.4 | 149 |

These parameters produced the following performance characteristics:
Boost/Sustain/Coast/Glide at g=45 degrees;
Boost (3.7 sec): Run with Mach=0 at 0 ft;
End-of-boost velocity (1408 ft/sec);
End-of-boost altitude (1836 ft);
End-of-boost range (2598 ft);
Sustain (10.9 sec): Re-run Mach=1.3 at 1836 ft;
End-of-sustain velocity (1586 ft/sec)
End-of-sustain incremental altitude (12863 ft)
End-of-sustain incremental range (18190 ft);
Coast (9.9 sec): Re-run Mach=1.5 at 14699 ft;
End-of-coast velocity (1102 ft/sec);
End-of-coast incremental altitude (8680 ft);
End-of-coast incremental range (12275 ft); and
Glide: Lift-to-Drag (L/D) max=5 at 23379 ft=116895 ft.

In summary:

| Flight Path Angle (Angle | | |
|---|---|---|
| between the velocity and | Incremental | Incremental |
| other reference direction) | Altitude | Range |
| γ = 45 degrees | (ft) | (ft) |
| Boost | 1836 | 1836 |
| Sustain | 12863 | 12863 |
| Coast | 8680 | 8680 |
| Total Altitude | 23379 | |
| Glide | | 116895 |
| Total Range | | 114274 |
| Total Range | | 23 nmi |

Another example of an application for the generative AI system is for component (or subsystem) of an aerospace vehicle system such as a jet engine (e.g., ramjet). Given a worst-case scenario (high combustion temperature) and working backward from thermal choking conditions, the generative AI system can determine the subsonic combustor entrance Mach number and subsequently, the inlet throat area. The range performance can be assessed assuming optimized aerodynamic properties.

The maximum thrust occurs at high combustion temperature and high fuel-to-air ratio, but insulation technology limits combustor temperature and fuel/air. Assume high combustor temperature T₄=4000 Rankine (“R”). From this thermally choked M₄=1 condition (M4 represents Mach number at the nozzle throat), the subsonic combustor entrance Mach number and the inlet throat area can be determined.

| | |
|---|---|
| Mach Number at Combustor Entrance | M₃ = 0.193 |
| Inlet Throat Area | 93.7 in² |
| Pressure Ratio between the Nozzle | p₄/p₃ = 0.79 (upper limit on the |
| Throat and the Combustor Entrance | throat area) |

Reducing the combustor entrance Mach number by 10 percent yields.

| | |
|---|---|
| Mach Number at Combustor Entrance | M₃ = 0.174 |
| Inlet Throat Area | 84.8 in² |
| Pressure Ratio between the Nozzle | p₄/p₃ = 0.79 (no additional |
| Throat and the Combustor Entrance | pressure loss) |

This reduces the inlet throat area to provide good specific impulse while satisfying the thrust requirement.
Cruise—Breguet Range Equation;
Given flight conditions: M=3 at 60 kilo-feet (“kft”)
(L/D) MAX=2.05 at 15.2 degrees angle-of-attack;
Maximum range is 568 nmi (3.5E+06 ft); and
Note: Wpropellant/WBeforeCruise=476 lb/1739 lb=0.27.

In the context of detection engineering, the generative AI system can be applied to systems thinking and reverse engineering to detect and characterize threats more accurately. The goal is to create an automated system of threat detection that is customizable, flexible, repeatable, and produces high quality alerts for security teams to act upon. Sensitivity of the unknowns such as lift-to-drag ratio, specific impulse, fuel type, fuel weight, mass of vehicle, fuel-to-mass ratio, time-to-target, destructive energy capacity, blast pattern, (or other measures of merit) etc. and how they impact confidence in range performance or delta-V performance capability may be reported. If intelligence assets are limited or available information is conflicting, cost-effective and insightful risk-based decisions are still enabled.

Another example of an application for the generative AI system is for the smallsat. Contemporary regions of conflict across the globe have highlighted the unprecedented use and success of drones to carry out strategic and tactical warfighting activities. These activities have varied from surveillance and support to actual seek-and-destroy missions of both soft and hard targets. It is not difficult to extrapolate these warfighting drone capabilities to the frontier of near-earth space scenarios and the consequences they might have on national security.

In the space environment, the smallsat is the closest analogy to the terrestrial drone. The envisioned mission is one where one or many such vehicles are deployed in the same or various staging orbits until a time where their seek-and-destroy services are called for. At that point, each of these small kill vehicles would be given a target location and an intercept trajectory would either be autonomously computed or provided by the initiating actor as part of the activation process. The vehicle would then carry out its mission plan by applying the specific velocity changes via its on-board propulsive capabilities toward the target, and then further wait (on its current coast arc) or immediately initiate a destructive means to disable or destroy any targets within the “kill”-, or “blast”-zone.

The perspective of this scenario is now reversed, i.e., how to best assure survival of assets by assessing “killer smallsat” system capabilities. There are several aspects to consider as set forth below. The operational range is one of those aspects. In the space environment, this often translates to the delta-V capacity of the smallsat. In turn, this translates to the propulsive characteristics of the smallsat. The fuel type, quantity and engine performance nozzle shape should be considered.

Another aspect is a destructive capacity of the smallsat including the method (e.g., high explosive, directed energy weapon, scatter, or buckshot) to carry out the mission. To that end, the destructive capacity may be lethal or disabling. The generative AI system should take into account spatial lethality gradients (i.e., do effects depend on discharge direction), and if the smallsat is continuously active, or can it wait indefinitely.

Another aspect are the resources to carry out its mission such as, without limitation, temperature moderation, and electrical power (constantly or intermittently, quantity, source (battery or solar recharge)). Another aspect is the operational lifespan of the smallsat. For instance, the smallsat could continue to be a passive threat even after a resource might be depleted.

Answers to each of these probing questions can be modeled and quantified by knowing exact characteristics of the system. Of course, precise information is not always known, and as such the AI model attempts to ascertain characteristics by using uncertainties via random variables in conjunction with “physics-based engineering equations.” (See, e.g., the description with respect to FIG. 10 above.)

As an example, consider the delta-V capability of the smallsat. Broadly speaking, smallsats are considered to be categorized in only one of three general brands, “nano”, “micro” and “mini”. Accordingly, the amount of fuel available to such systems is on the order of less than 1, 7, and 50 liters per mass ranges of 1-10, 10-100, and 100-500 kgs, respectively. Compared to more traditional, operational satellites, the total propulsion system dry mass fractions for smaller-end of small-sats are often much higher and have increasingly greater dependencies on other quantities such as molecular fuel mass and densities. This dependency radically modifies the traditional rocket equation that equates specific propellant usage to generative delta-V capacity via a specific impulse constant, Isp. Instead, the governing equations use system-specific impulse, Issp as developed by Zakarov, et al.

About ten different fuel type systems are considered using less-expensive and less-caustic propellants and propulsive structural plumbing mass. As the range of total vehicle mass and total propulsive system dry mass fractions are considered and optimized for maximum delta-V capacity by modelling equations within the process, likely fuel and propulsive characteristics are assessed and quantified.

Once having a likely delta-V estimate, one can then follow-up with further threat assessment considerations by similar generative AI processing techniques. For example, Lambert's orbital transfer/targeting equations can be used to determine if an intercept trajectory from the killer smallsat to the asset is feasible, and to what degree of likelihood. Guidance variability effects and kill-probabilities can then also be acquired.

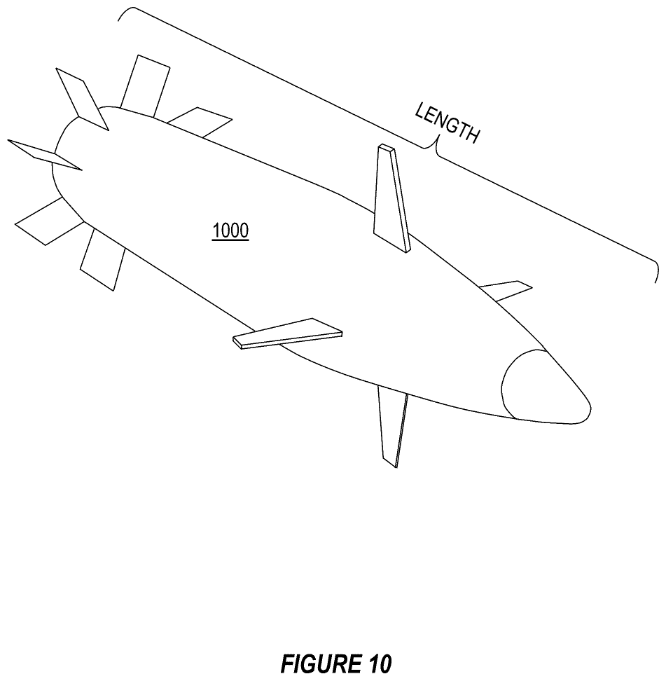

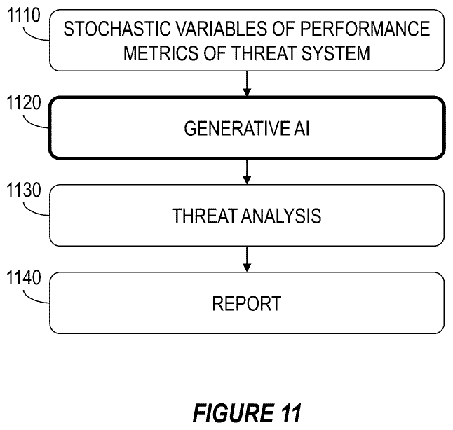

FIG. 11 illustrates a flow chart of a method or process to determine a threat analysis. For example, a threat system (e.g., an aerospace vehicle system such as Russian Zircon hypersonic cruise missile) may be obtained from intelligence sources. By gathering performance metrics (estimates represented by stochastic variables) of the threat and applying them as inputs (received and stored in memory) to the generative AI system 1120, the results are quantifiable capabilities of the threat analysis 1130. In this MBSE/MDO embodiment, the generative AI system 1120 contains (stored in memory) the first-order physics-based engineering (mathematical) equations (relationships, a plant model) of aerodynamic efficiency, propulsion efficiency, velocity, mass properties, etc. When executed on a processor, the generative AI system 1120 performs this analysis in a single step (or iteration) improving computational efficiency and reducing power consumption and other resources of the processor operating the generative AI system 1020 by reducing iterations to produce the threat analysis 1130. Conventional architectures do not use the same architecture (the generative AI system's 1120 first-order physics-based engineering equations, for instance, of aerodynamic efficiency (e.g., lift-to-drag ratio), propulsion efficiency (e.g., specific impulse), velocity, mass properties (e.g., weight of propellant (or fuel) relative to the overall weight of the vehicle), etc.) and produces a threat analysis 1130 (e.g., maximum Mach number) from existing observations with uncertainty (e.g., compression inlet deflection angle of a ramjet).

Furthermore, (optimal) performance metrics (extracted automatically from the stochastic variables 1110) are reported (reported performance metrics 1140), including sensitivity analyses of the performance metrics, such that the system engineer can immediately identify performance drivers for the threat analysis 1130 to monitor, and/or provide countermeasures to address the threat analysis 1130. Of course, a multitude and diversity of domains can be applied to the generative AI system 1120 to produce the threat analysis 1130.

Each of the domains in the processes described herein have been explicitly defined with mathematical relationships including their interdependencies to each other and their overall impact on the threat analysis. In contrast to the conventional systems that dictate single point values of process parameters, the generative AI system accepts stochastic ranges of input performance metrics. In other words, the input metrics are randomly determined; having a random probability distribution or pattern that may be analyzed statistically but may not be predicted deterministically. This capability is very important when designing future processes that are subject to uncertainty such as the threat analysis is a likelihood of occurrence. Depending on the generative probe, these metrics may be adjusted or refined to fit the circumstances.

From this stipulated scenario, the generative AI system creates an optimally designed process. This is performed by modulating independent performance metrics (in accordance with executing the first-order physics-based engineering equations) until the multi-dimensional combination arrives at a threat analysis with the optimal (maximum or minimum) performance metrics. This threat analysis may include unobvious decisions, analysis points near sharp discontinuities in value, and/or stochastic ranges of analysis based on uncertain assumptions.

The generative AI system is applicable to any process or system that can be defined mathematically and has the need for rapid creation of optimal designs. Illustrative use cases are described herein, although other use cases are comprehended. Those skilled in the art will appreciate the complexity of these questions and the benefit of creating optimal solutions in a rapid timeframe. It should be noted that each of these described use cases employ high fidelity plant models that are highly non-linear, discontinuous, noisy, and uncertain.

As an example, generating previously unavailable defense training datasets is an important component for any threat analysis for a military organization. There are multiple emerging weapon systems that are known or expected, but of which very little operational data is available such as hypersonic missiles, directed energy weapons, and agile electronic warfare jammers. Counter measures to these systems are critical to national defense, however training, testing, and qualifying these counter measures require data. By means of the generative AI system, a plant model specific to these known unknown weapon systems can create synthetic operational data that can be used to test, harden, vet other artificial intelligence/machine learning methods, and derive action plans to prevent the potential threat. The benefits to this approach are readily seen as set forth below as applied to hypersonic missiles.

An example of an application for the generative AI system is for threat modeling, simulation, and assessment analysis, for a component (subsystem) of an aerospace vehicle system. Advanced simulation techniques are needed to develop hypersonic missile threat assessments, as a cost-effective alternative, especially in a typical case of incomplete information. Current notional defense against hypersonic missiles lies somewhere between exoatmospheric ballistic missile defense and subsonic or supersonic cruise missile defense. Hypersonic glide and hypersonic cruise missiles have trajectories that lie within the atmosphere, and they travel at hypersonic speed such as a Mach number greater than five. These partial overlapping threat assessment approaches require the generative AI system.

To aid in this threat assessment, a digital twin missile model is built to simulate and parametrically estimate performance subject to uncertainties. This model can provide valuable insight through quick and inexpensive simulation. This disclosure presents how the digital twin model is built for simulation based on first-order, physics-based engineering equations of aerodynamics and propulsion, where threat assessment is measured in the form of range capability and other performance measures (e.g., kinetic impacts). The model is verified by checking each equation with example calculations and validated with three baseline missiles such as a rocket-powered air-to-air missile, a ramjet-powered advanced strategic air-launched missile, and a turbojet-powered antiship missile.

Next, an application of hypersonic missile threat assessment based on publicly available or interpretable information of the Russian Zircon hypersonic cruise missile is presented. Finally, the sensitivity of the unknowns (lift-to-drag ratio, specific impulse, fuel type, fuel weight, or other measures of merit etc.) and how they impact confidence in range performance capability is demonstrated. Therefore, if intelligence assets are limited or available information is conflicting, cost-effective and insightful risk-based decisions are still enabled.

The United States hypersonics began in 1947 when the National Advisory Committee for Aeronautics (NASA's predecessor) established a hypersonic wind tunnel at Langley, Virginia. Since then, numerous experimental programs have researched propulsion, materials, and structures leading to more recent testing programs such as the X-43 supersonic ramjet (scramjet) attaining Mach 9.6 in 2001. These programs are typically organized into two classes, namely, hypersonic glide vehicles (“HGV”) and hypersonic cruise vehicles (“HCV”). The HGVs typically operate with rocket propulsion and glide, whereas the HCVs operate with airbreathing propulsion and cruise. Both vehicles maneuver using aerodynamic surfaces, and this maneuverability is crucial, unlike ballistic vehicles.

Ballistic vehicles, such as intercontinental ballistic missiles, are launched with rocket propulsion and lack maneuverability. Therefore, their trajectories may be determined early in flight, making them relatively easy to intercept. Even without interception, these ballistic trajectories result in a small impact area. However, HGVs and HCVs can maneuver with glide and cruise capabilities, and they do not have to be lofted high into the atmosphere. This makes determining their trajectories extremely difficult. Factor in their hypersonic speed and one realizes there is little time for decision-making when it comes to threat neutralization.

The Hypersonic Program History Table (Norris 2022) shows a history of various experimental hypersonic glide and cruise (airbreathing) vehicle programs and their outcomes over the past half century. Prior to 1980, there were many hypersonic reentry vehicle tests, which led to the success of the Space Shuttle program beginning in 1981.

Hypersonic Program History

| Year | Description | Outcome |
|---|---|---|
| 1978 | Advanced Manned Spaceflight | Not flown, canceled in 1986 |
| | Capability | |
| 1979 | Advanced Maneuverable Reentry | Flown |
| | Vehicle | |
| 1982 | DARPA Copper Canyon | Not flown, canceled in 1990s |
| 1896 | X-30 National Aerospace Plane | Not flown, canceled in 1990s |
| 1995 | NASA's X-34 | Not flown, canceled in 2001 |
| 1996 | NASA's X-33 | Not flown, canceled in 2001 |
| 2001 | Scramjet X-34 | Mach 7 and Mach 9.6 in 2004 |
| 2002 | HyFly (dual combustion ramjet) | Final attempt failed in 2010 |
| 2010 | X-37B (based on X-37A) | First orbital mission |
| 2010 | X-51A (wave rider) | Mach 5.1 and 210 sec flight |
| 2010 | Hypersonic Test Vehicle 2 | Unsuccessful flight |

However, by examining the “outcomes” column, it is apparent that technical challenges, flight test failures, and cancelations resulted in repeated short term hypersonic programs. The associated knowledge loss and talent atrophy needs to be re-established when a new program starts. In the present day, the United States has persevered with hypersonics research and development. The Current Hypersonic Prototype Programs Table (Sayler 2023) shows the known unclassified government hypersonic prototype weapon programs currently funded by the Department of Defense (“DOD”).

Current Hypersonic Prototype Programs

| Agency | Program | Status |
|---|---|---|
| DARPA | Hypersonic Airbreathing Weapon | Ground testing FY23 |
| | Concept (“HAWC”) | |
| DARPA | Tactical Boost Glide (“TBG”) | Third test flight FY23 |
| USA | Long Range Hypersonic Weapon | Prototype deployment |
| | (“LRHW”) | FY23 |
| USAF | Air-launched Rapid Response | Canceled, March 2023* |
| | Weapon (“ARRW”) | |
| USAF | Hypersonic Attack Cruise Missile | Test/development FY27 |
| | (“HACM”) | |
| USN | Conventional Prompt Strike (“CPS”) | Deployment FY25 |

Since the DOD has not established any programs of record for hypersonic weapon acquisition, contributing to the United States losing its hypersonics lead to China and Russia, all the programs in the table are prototypes. It remains to be seen which will emerge as the most cost-effective solution. It appears that these weapons will be conventionally armed, which requires a precision strike.

To counter the United States' effective ballistic missile defense systems, China and Russia have developed hypersonic threats. Due to their nuclear capability, precision is not required, hence their rapid development. China fielded the DF-ZF HGV in 2020 and is currently in the process of developing a “wave rider” called Starry Sky-2 (Sayler 2023) that will be operational by 2025. Meanwhile, Russia has an HGV (Avangard) boosted by an Intercontinental ballistic missile (“ICBM”), a ship-launched HCV (Tsirkon/Zircon), and an air-launched ballistic missile (Kinzhal/Daggar) that has been used in Ukraine. As mentioned previously, because these are hypersonic threats, there is little time for decision-making in a scenario where these are deployed. With the inconsistency of United States development programs, there may be limited human resources with topical knowledge. As such, the generative AI system can assess hypersonic threats with limited knowledge in a timely manner.

As set forth herein, the generative AI system applies hypersonic threat modeling, verification and validation, simulation, and assessment, which can be used to gain valuable insight quickly and inexpensively. Simulation of the model is applied to demonstrate how decision-makers may aggregate threat assessment and how uncertainty may impact confidence in performance capability. Therefore, if intelligence assets are limited or available information is conflicting, cost-effective, and insightful risk-based decisions are possible.

To simulate and assess threats, a digital twin model of generic hypersonic glide/cruise vehicles is employed. One of the earliest researchers is Fleeman (2001, 2012) who presents a comprehensive approach to first-order conceptual missile design and system engineering. A first-order approach is more than sufficient to gain the necessary insight. In the text, Fleeman guides the design process, introducing the necessary physics-based engineering equations describing aerodynamics, propulsion, mass properties, structures, aerothermal heating, and flight performance metrics among other measures of merit. Accompanying the text, Fleeman provides an Excel spreadsheet (Spears, et al. 2022) to perform calculations associated with the design process. To facilitate reverse engineering for threat analysis, it is beneficial to have the physics-based engineering equations available on a platform with optimization capability. This platform and the benefit of optimization for reverse engineering will be described herein.

Describing the challenges of hypersonic flight, Bowcutt (2022) discusses the need for multidisciplinary design optimization due to the increased design/performance uncertainties associated with hypersonic flight. This is yet another motivation to build the model on a platform capable of optimization, and to accommodate uncertainty with stochastic input variables. This platform and related papers have been presented to Interservice/Industry Training, Simulation and Education Conference (“I/ITSEC”) over recent years (Allen 2019, 2020, 2021).

When assessing missile threats, its beneficial to know the range of the threat for countermeasure purposes. If the threat is ballistic, modified projectile motion equations may be applied for range analyses. However, since our interest is hypersonic glide/cruise missiles, different equations are required. For glide vehicles, range is simply a function of altitude and the lift-to-drag ratio, which is based on the aerodynamics of the vehicle. For cruise vehicles, range is more complicated due to propulsion, but the Breguet range equation to follow provides an answer:

$$R = {V}_{A V G} {I}_{S P} ( \frac{L}{D} ) ln ( \frac{{W}_{B C}}{{W}_{BC} - {W}_{P}} ) ,$$

where R is range, V_{AVG} is average velocity, I_{SP} is specific impulse, L/D is the lift-to-drag ratio, W_{BC} is the weight of the vehicle before cruise, and W_{P} is the weight of the propellant (Fleeman, 2012, p. 127).

The weight of the vehicle before cruise and the weight of the propellant can be in any units, provided they are consistent such that the ratio of the natural log argument is dimensionless. Typically, units of pounds are used for weight. The lift-to-drag ratio is based on the aerodynamics of the vehicle. It too is dimensionless because lift and drag are given in consistent units. Specific impulse is a measure of propulsion efficiency, measured in units of seconds. The higher the specific impulse, the more efficient the propulsion system is at generating thrust. Finally, the average velocity may be in any unit of velocity provided that the denominator is in seconds to cancel with specific impulse (thus providing range in units of its numerator). For example, if the average velocity is measured in feet per second, then range will be measured in feet.

In summary, the Breguet range equation is a measure of the vehicle's velocity, propulsion efficiency, aerodynamic efficiency, and weight characteristics. These are the four areas that need to be accounted for when performing threat analysis in terms of range capability. However, the analyst is not given these four parameters to be used in the Breguet range equation. Instead, there are other physics-based engineering equations that lead to these parameters of, for example, lift-to-drag ratio. Similarly, a measure of aerodynamic efficiency may be estimated by examining flight conditions such as Mach number, altitude, and an aerodynamic parameter called angle-of-attack. This will be discussed below.

Before a model is used for simulation, it must be verified and validated. Verification is the process of ensuring that the model is built correctly. Validation is the process of ensuring that the correct model is built. For example, a model may be developed to compute Newton's second law, which states that the sum of the external forces on an object is proportional to the rate of change of its momentum. This equation can be verified through several tests to make sure it is implemented correctly. If so, the model is considered verified, that is, it is built correctly. When it is time for validation, the model is presented to stakeholders to make sure it meets the requirements. At this time, if it is discovered the model is intended to be used for special relativity (where Newton's second law is invalid) and the model should have implemented Einstein's equation (E=mc²) instead, then the incorrect model has been built and is thus invalid. With this understanding, verification and validation is applied to the generic hypersonic glide/cruise model.

Each of the model's approximately three hundred physics-based engineering equations are verified by comparing individual results with sample calculations found in Fleeman's textbook, extensive course notes, or in some cases, direct correspondence. The process of modeling and verifying the equations takes several weeks. After verification, the model is then validated.

The model is validated using three baselines (Fleeman 2012). The first baseline is a rocket-powered air-intercept missile, where aerodynamic and propulsion computations are validated by assessing maximum range performance. With this baseline, the maximum range is measured for a boost, sustain, coast, and glide scenario. This baseline may also be used to measure ballistic range performance where, instead of gliding, the vehicle is left to follow projectile motion after the boost-sustain-coast flight phase.

The second baseline is a ramjet-powered cruise missile. Maximum range performance is measured by the Breguet range equation referenced above. This baseline validates all the calculations serving as inputs to the range equation (e.g., aerodynamic lift-to-drag ratio and propulsive specific impulse). The third baseline is a turbojet-powered antiship cruise missile. Again, the Breguet range equation is the performance metric.

The first baseline scenario most closely represents a hypersonic glide vehicle, which is typically boosted under rocket power. Rockets can in fact boost vehicles to hypersonic speeds. After separation, the hypersonic glide vehicle maneuvers to its destination. Both the second and third baseline scenarios most closely represent a hypersonic cruise vehicle. Ramjets operate efficiently at supersonic flight conditions and can operate at hypersonic flight conditions up to approximately Mach 6. These vehicles are boosted with either a rocket motor or a turbojet engine to attain supersonic conditions for the ramjet to begin operation, in a process called “startup.” The other major engine type is the scramjet, a supersonic combustion ramjet. This is the current technology used in hypersonic cruise vehicles, and it will be addressed below.

With a fully verified and validated model (developed on a platform with optimization capability), the threat analyst can maximize range performance (e.g., Breguet in the case of a hypersonic cruise vehicle) and observe the parameters leading to such a solution (e.g., aerodynamic lift-to-drag ratio and propulsive specific impulse) for various conditions (Mach number, weight before cruise, and propellant weight).

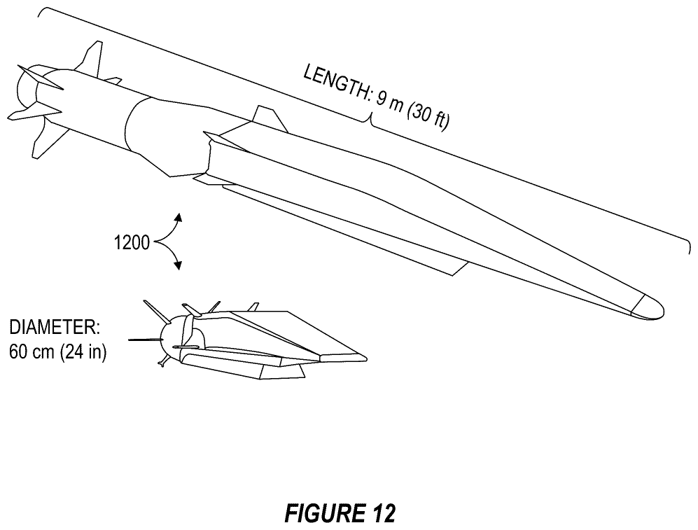

Now that the digital twin model of generic hypersonic glide/cruise vehicles is verified and validated, it allows decision-makers to aggregate threat assessment through simulation. What follows is a threat assessment of Russia's Zircon (Tsirkon) missile 1200 (Zircon 3M22), shown in FIG. 12, where the data used for this analysis is publicly available from Defense News (2023). The engine is a scamjet that relies on supersonic airflow, and the warhead is conventional, possibly nuclear. The first action is to select a baseline from the model options: rocket-, turbojet- or ramjet-powered. Since Zircon is a hypersonic “airbreather,” the ramjet baseline is chosen.

The aerodynamic coefficients, namely, coefficient of lift and coefficient of drag, which lead to the lift-to-drag ratio (“L/D”), are obtained from a set of equations based on the body geometry and each aerodynamic surface (that is, canards, wings, and tail). Therefore, there is no need to perform computational fluid dynamics (“CFD”) simulations that take hours, days or weeks. The model simply needs geometric inputs and aerodynamic surface inputs, which are publicly available and interpretable from FIG. 12. The Geometric Data Table summarizes the (given) geometric data, and the Aerodynamic Surface Data Table summarizes the (interpretable) aerodynamic surface data.

Geometric Data

| | |
|---|---|
| Body Diameter (in) | 24 |
| Body Length (in) | 360 |

Aerodynamic Surface Data

| | Wing Section | Tail Section |
|---|---|---|
| Mean Aerodynamic Chord (“MAC”) (in) | 9 | 9 |
| Sweep Angle (deg) | 45 | 10 |
| Span (in) | 9 | 27 |
| Area (in²) | 122 | 243 |
| MAC Location (in from nose) | 234 | 333 |

The data in the Geometric Data Table is taken directly from FIG. 12. The data in the Aerodynamic Surface Data Table is estimated by using FIG. 12 and scaling it to measure various lengths. For example, holding a ruler to FIG. 12, a scale of 30 feet equaling 7⅜ inches can be used. Estimating the length (span) of one of the tail sections to be 9/16 inches, produces a scaled tail span of 27 inches (third entry under tail section). The other parameters are estimated likewise. Since the geometric parameters are given, these inputs are represented deterministically. In contrast, the aerodynamic surface data is estimated, so their inputs are represented by stochastic variables.

A point to be made here is that the geometric parameters could be stochastic as well. For example, if the length and diameter are not known, one could assess a class of missiles that fit a type of application and use a distribution to represent these geometric properties. Ideally, their impact is measured to see just how much this matters on the overall performance metric. This will be demonstrated below. Returning to the topic of lift-to-drag ratio, the aerodynamic coefficients cannot be reported from the geometry or aerodynamic surface data alone because they also depend on the flight conditions such as Mach number, altitude, and angle-of-attack.

Propulsive specific impulse (“I_{SP}”) is obtained from a set of equations based on properties associated with the ramjet engine. The Ramjet Specific Impulse Data Table summarizes the data associated with the specific impulse calculation. Some of these are not determinable, and others are difficult to determine from FIG. 12. Therefore, ramjet baseline parameters are used instead. This is why it is important to begin with a relevant baseline for threat analysis.

Ramjet Specific Impulse Data

| | |
|---|---|
| Fuel Heating Value (BTU/lbm) | Ramjet Baseline |
| Combustor Fuel-to-Air Ratio | Ramjet Baseline |
| Combustion Time (sec) | Ramjet Baseline |
| Combustion Velocity (ft/sec) | Ramjet Baseline |
| Combustor Flame holder Entrance Area (in2) | Ramjet Baseline |
| Inlet Throat Area (in2) | Ramjet Baseline |
| Inlet Height (in) | Ramjet Baseline |
| Inlet Location (in) | Ramjet Baseline |

For a ramjet engine, the fuel is typically liquid RJ-5 with a density of 0.037 lbm/in³ and a volumetric performance of 650 BTU/in³, yielding a heating value of approximately 17,600 BTU/lbm. This is a driving parameter for specific impulse and impacts range performance. The other piece of information related to propulsion is the propellant weight as well as the weight of the vehicle before cruise. Since these parameters are currently unavailable, the ramjet baseline values are used.

The last set of data needed for threat analysis is the flight conditions. The Wikipedia article (https://en.wikipedia.org/wiki/3M22_Zircon) says the operational altitude is 92,000 ft at Mach 9. The angle-of-attack for maximum range is not provided, but the model's optimization platform is leveraged as shown below. Of note, while Mach 9 exceeds the efficient operation of a ramjet engine (Mach 6), the baseline is the best currently available.

Having initialized the aerodynamic data (geometry and surfaces), the propulsion data (ramjet baseline), and the flight conditions, the simulation is executed to determine the maximum cruise range. Inputs and outputs that impact the Breguet range equation are summarized in the Inputs and Outputs for Threat Range Table. To simplify the table, the angle-of-attack is represented by α, average velocity is represented by V_{AVG}, fuel heating value is represented by Hf, weight before cruise is represented by W_{BC}, and propellant weight is represented by W_{P}.

Inputs and Outputs for Threat Range

| Mach | Altitude (ft) | α (deg) | V_{AVG} (ft/s) | Hf (BTU/lbm) | W_{BC} (lb) | W_{P} (lb) |
|---|---|---|---|---|---|---|
| 9 | 92,000 | TBD | 8707 | 17,600 | 4644 | 449 |

Currently, the angle-of attack is unknown (see the third column of the Inputs and Outputs for Threat Range Table), so it is represented by a stochastic variable over a range of values from 0 to 25 degrees. A simulation of the model is executed with this uncertainty in the angle-of-attack results in a wide uncertainty range between 48 nautical miles (“nmi”) and 488 nmi, with a median range of 415 nmi. Hence, there is downside to angle-of-attack uncertainty.

The angle-of-attack is not going to be determined from FIG. 12, nor is it generally reported in the literature. However, using the optimization platform, it may be determined by maximizing the lift-to-drag ratio for the given flight conditions (Mach 9 at an altitude of 92,000 ft). This results in an angle-of attack of 13 degrees. With this value used deterministically, the range is 492 nmi, with no variance. This is lower than the Wikipedia reported range capability of 540 nmi.

Recall the heating value is set for a baseline ramjet (RJ-5) fuel. The Wikipedia page says the fuel is JP-10. Different varieties of JP-10 fuel with their respective heating values are as shown in JP-10 Fuel Attribute Table.

JP-10 Fuel Attributes

| Variant | Heating Value (BTU/lbm) |
|---|---|
| 40% JP-10, 60% Aluminum | 12,028 |
| 40% JP-10, 60% Carbon | 16,347 |
| 40% JP-10, 60% Boron | 23,820 |

By changing the heating value from 17,600 BTU/lbm (RJ-5) to a high-performance variant of JP-10 with a heating value of 23,820 BTU/lbm, the maximum range performance is improved to 652 nmi. The Wikipedia page states further that the Zircon missile can attain ranges from 1000-2000 km (540-1080 nmi). This extra range performance may be picked up with additional propellant weight, different flight conditions, or better fuel. Note that the optimization platform maximizes the lift-to-drag ratio, thus fixing the angle-of-attack for the given Mach number and altitude (Mach 9 at 92,000 ft, respectively). Also, by introducing a Zircon specialized fuel with higher performance (JP-10), the model simulated maximum range performance within the envelope presented in the Wikipedia Zircon article.

Let us assume there is no knowledge of flight conditions such as Mach, altitude, angle-of-attack, heating value of the fuel, or weight of the propellant. Instead, we assume a variance for each parameter as shown in the Input Parameter Bounds Table. For example, Mach number can be anywhere between 6 and 9.

Input Parameter Bounds

| Parameter | Lower Bound | Upper Bound |
|---|---|---|
| Mach | 6 | 9 |
| Altitude (ft) | 1,000 | 92,000 |
| Angle-of-Attack (deg) | 0 | 20 |
| Heating Value (BTU/lbm) | 17,000 | 30,000 |
| Propellant Weight (lb) | 500 | 1,000 |

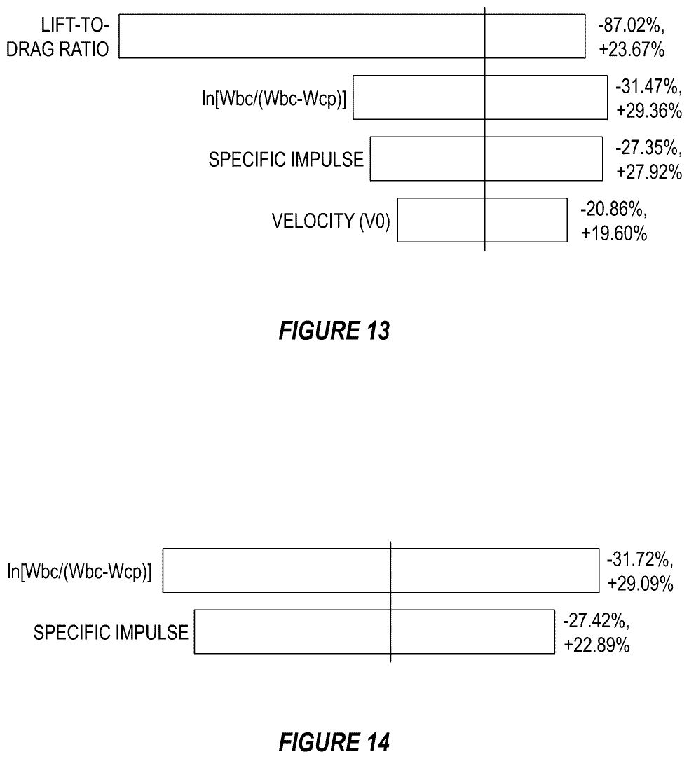

Accounting for all this uncertainty, the median maximum range is 718 nmi and the sensitivities of the inputs are ranked in the tornado chart with variance of all inputs of FIG. 13. In this FIGURE, lift-to-drag ratio is contributing the most uncertainty to range performance with a low value of −87% (93 nmi) and a high value of +24% (890 nmi). Next is the natural log term (which is a function of the weight before cruise and the propellant weight), then the specific impulse, and finally velocity.

As mentioned previously, the angle-of-attack, which is the driver for lift-to-drag ratio, is not going to be reported. Therefore, optimization is leveraged again to maximize lift-to-drag ratio. In this case, however, the Mach number and altitude are also allowed to vary. The result is an angle-of-attack of 11 deg at Mach 9 and 28,000 ft yielding a median maximum range of 1,107 nmi (slightly over 2,000 km). From a threat perspective, if the Russians risk flying at a lower altitude (28,000 ft vs 92,000 ft), then cruise range is extended. However, they are probably trading range for survivability (a measure of merit).

With the angle-of-attack, Mach number, and altitude set to their deterministic values, the remaining uncertainties are propellant weight and specific impulse (fuel heating value). From the tornado chart with variance of remaining inputs of FIG. 14, both have approximately the same impact on maximum range performance. Therefore, from an intelligence-gathering perspective, the type (heating value) and amount of fuel (propellant weight) are critical for threat analysis, in addition to a picture of the vehicle.

The conclusion suggests using the optimization platform for maximizing the lift-to-drag ratio to fix the three flight conditions (Mach number, altitude, and angle-of-attack). The two remaining parameters (propellant weight and fuel heating value) are to be determined. If the fuel is known (e.g., JP-10), then the last question to answer is “How much propellant is loaded into the vehicle?” If there are limited intelligence assets, this is the parameter to focus on.

Although there are no programs of record yet, there is a resurgence of hypersonic research and development in the United States. Meanwhile, China and Russia have developed and fielded hypersonic threats (both glide vehicles and cruise vehicles). Because of the inconsistency of United States' programs, there are fewer knowledgeable individuals to assess these (or other) threats. Therefore, a model is introduced to simulate threat analysis to gain valuable insight quickly and inexpensively.

The model is built with over 300 physics-based engineering equations, which are verified and validated with three baselines (rocket-, turbojet-, and ramjet-powered propulsion). Based on multiple iterations of experiments, the results suggest that the ramjet baseline is used to perform threat analysis of Russia's Zircon hypersonic cruise vehicle. The Breguet range equation serves as the performance metric with inputs of average speed, specific impulse, lift-to-drag ratio, and a factor dependent upon propellant weight. Average speed and lift-to-drag ratio are functions of the flight conditions (Mach number, altitude, and angle-of-attack), while specific impulse is a function of the fuel heating factor.

The results show that the ramjet baseline (in lieu of a scramjet) is adequate for hypersonic cruise vehicle threat analysis. Also, using given flight conditions (Mach number and altitude) and fuel type (heating value), the model computes maximum range performance results in line with reported capabilities. Furthermore, with no knowledge of the flight conditions, sensitivity analysis shows that two parameters, namely, type of fuel (heating value) and amount (propellant weight) are where intelligence assets should focus.

From a simple photograph, decision-makers can model and simulate threat analyses to determine countermeasures in minutes. Because the aerodynamics are built-up section-by-section, there is no need to run computational fluid dynamics (“CFD”) simulations over the course of hours or days to a mass aerodynamic coefficients. Even without a photograph, a class of missiles that fit a type of application (e.g., cruise missiles) could be cataloged from known data, and statistical distributions could represent geometric properties (e.g., body diameter, body length, and aerodynamic surface properties). Thus, their impact is measured to see just how much this matters on the overall performance metric.

While the ramjet baseline serves as the best option for hypersonic cruise vehicles, a scramjet propulsion system can be modeled, verified, and validated for a more complete hypersonic threat simulation. Recall that ramjets operate efficiently near Mach 5 to Mach 6. However, Zircon cruises at Mach 9, exceeding the ramjet operational range. Work has already begun to incorporate the physics-based engineering equations from Heiser & Pratt (1994) and Bertin (1994). Equations for compression, combustion, and expansion have been implemented into the model, including thrust, specific impulse, and efficiencies for performance assessment. Verification and validation can also be done.

While the analysis focused on the Zircon hypersonic cruise vehicle, the analysis was based on the cruise portion of Zircon's flight. To get to hypersonic speed, of course, Zircon is boosted with a solid rocket motor like hypersonic glide vehicles. The model has a separate rocket-powered baseline, rocket propulsion integrated with other propulsion baselines (turbojet, ramjet, and scramjet) to form what is called multistage propulsion. For example, one system might be an airbreathing multistage propulsion concept beginning with the turbojet (0-2 Mach), transitioning to the ramjet (2-5 Mach), and finally the scramjet (5-X Mach). This is similar to the single-stage-to-orbit (“SSTO”) X-30 National Aerospace Plane mentioned above.

After integrating all propulsion options, aerodynamics will be integrated so that there is interdependence between the subsystems. This is important with hypersonic vehicles because the shape of the body is part of the propulsion system, where the forebody serves as the inlet, and the aft body serves as the expansion nozzle. With the integration of these subsystems the platform enables multidisciplinary design optimization, a process to simultaneously account for geometric trade studies for aerodynamics and propulsion. Finally, from a logistics perspective, imaging obtained by various platforms should be integrated with a priori knowledge to assess performance faster than time to impact.

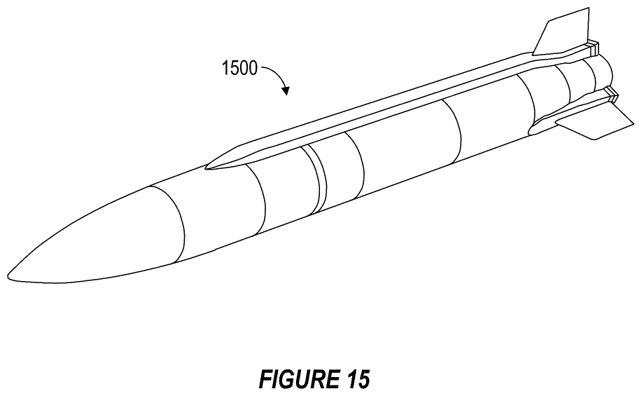

FIG. 15 illustrates a perspective view of an embodiment of an aerospace vehicle system 1500 demonstrating the application of the generative AI system. In this example, the aerospace vehicle system 1500 is a Kh-1010 Kodiak air-launched cruise missile (“ALCM”). Information about the Kh-101 Kodiak can be found at
https://missilethreat.csis.org/missile/kh-101-kh-102/
https://www.military-today.com/missiles/kh_101.htm
https://bulgarianmilitary.com/2023/02/03/russia-uses-kh-101-cruise-missile-upgraded-to-fire-thermal-traps/
https://www.globalsecurity.org/wmd/world/russia/kh-101-specs.htm,
   which are incorporated herein by reference.

Working from a turbojet (Harpoon) baseline:

### Geometry

Length=293 in (given), Diameter=20 in (given), Nose length=32.6 in (estimate)

### Surface Sizing Estimates

Canards: none
Wings: 1 set, chord=66 in, span=118 in (given), sweep=18 deg, planform area=8807 in², mac=130 in
Tails: 1.5 sets, chord=15 in, span=66 in, sweep=10 deg, planform area=243 in², mac=277 in

### Flight Conditions

Altitude=20 kft (given), Mach number=0.78 (given)

### The Generative AI System Determines (L/D) MAX Occurs at 4 Degrees Angle-of-Attack for:

Fuel weight=2755 lb, and
Maximum range=1069 nmi=1980 km.
   Cited range is 2500 km-2800 km:

| Launch Altitude (ft) | Range (nmi) | Range (km) |
|---|---|---|
| 20,000 | 1069 | 1980 |
| 10,000 | 1122 | 2078 |
| 5,000 | 1148 | 2126 |

This is assuming a slurry fuel (40% JP-10, 60% Boron) with the heating value of the fuel representing volumetric performance (“Hf”)=23,800 BTU/lbm; improving the fuel's heating value to 30,000 BTU/lbm delivers a range of 1343 nmi (2487 km).

| Parameter | Low | High |
|---|---|---|
| Angle-of-Attack (degrees) | 0 | 20 |
| Mach Number | 0.58 | 0.78 |
| Altitude (ft) | 5,000 | 20,000 |
| Fuel Heating (BTU/lbm) | 15,000 | 30,000 |
| Fuel Weight (lbm) | 2,000 | 3,000 |

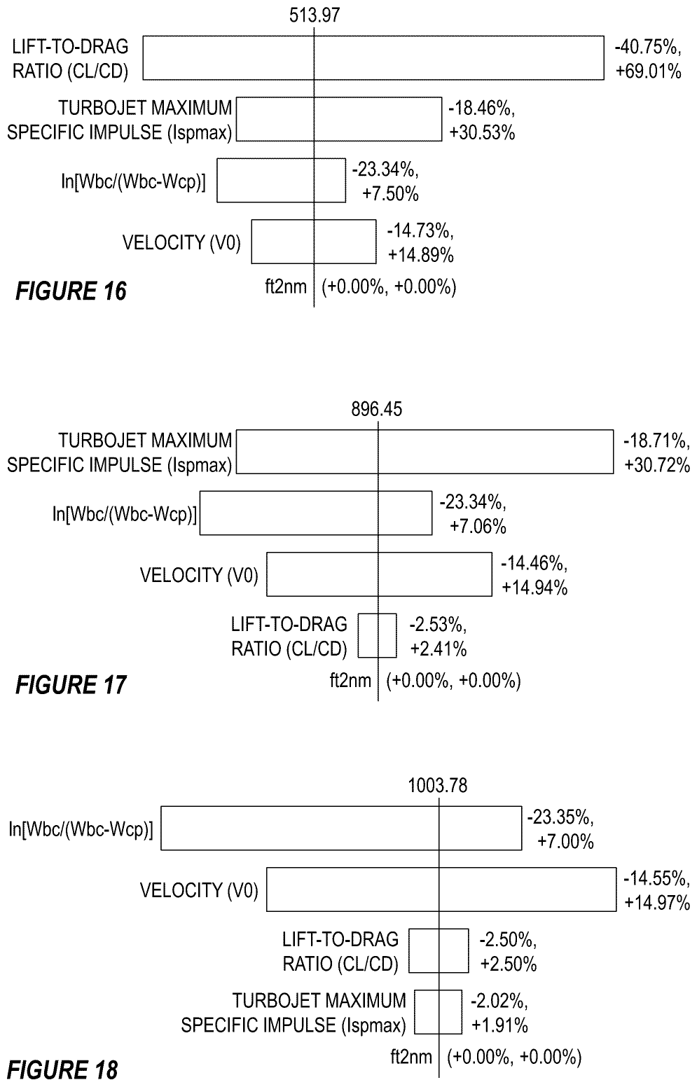

FIGS. 16 to 18 illustrate tornado charts employing the Breguet equation within a generative AI model that demonstrate uncertainties to the design created by the generative AI system. As shown in FIG. 16, the angle-of-attack (Lift-to-Drag Ratio) contributes the most uncertainty.

| | | Possible | Likely | | Likely | Possible |
|---|---|---|---|---|---|---|
| Node | Layer | Low | Low | Nominal | High | High |
| Maximum | New | 264.79 | 386.47 | 512.52 | 681.93 | 953.30 |
| Cruise | Model | | | | | |
| Range | Layer | | | | | |
| (Breguet) | | | | | | |

As shown in FIG. 17, now fuel heating (Turbojet Maximum Specific Impulse) contributes the most uncertainty.

| | | | | | Like- | Pos- |
|---|---|---|---|---|---|---|
| | | Possible | Likely | Nomi- | ly | sible |
| Node | Layer | Low | Low | nal | High | High |
| Maximum | New | 637.35 | 786.56 | 899.08 | 1,014.96 | 1,180.27 |
| Cruise | Model | | | | | |
| Range | Layer | | | | | |
| (Breguet) | | | | | | |

As shown in FIG. 18, finally fuel weight (Wbc) contributes the most uncertainty.

| | | Pos- | Like- | | Like- | Pos- |
|---|---|---|---|---|---|---|
| | | sible | ly | Nomi- | ly | sible |
| Node | Layer | Low | Low | nal | High | High |
| Maxi- | New | 872.04 | 941.61 | 1,003.44 | 1,059.85 | 1,123.24 |
| mum | Mod- | | | | | |
| Cruise | el | | | | | |
| Range | Layer | | | | | |
| (Breguet) | | | | | | |

When uncertainty is minimized, a nominal range with minimal variance is set forth below.

| | | | | | Like- | Pos- |
|---|---|---|---|---|---|---|
| | | Possible | Likely | | ly | sible |
| Node | Layer | Low | Low | Nominal | High | High |
| Maximum | New | 1,068.23 | 1,095.62 | 1,121.96 | 1,144.65 | 1,166.98 |
| Cruise | Model | | | | | |
| Range | Layer | | | | | |
| (Breguet) | | | | | | |

Information about the 3M22 Zircon (see FIG. 12) can be found at:
https://www.defensenews.com/naval/2023/01/05/russias-hypersonic-missile-armed-ship-to-patrol-global-seas/, and
https://en.wikipedia.org/wiki/3M22_Zircon,
   which are incorporated herein by reference.

Working from a ramjet (ASALM) baseline (flight conditions dictate supersonic combustion, scramjet):

### Geometry

Length=360 in (given), Diameter=24 in (given), Nose length=108 in (estimate)

### Surface Sizing Estimates

Canards: none
Wings: 2 sets, chord=9 in, span=9 in, sweep=45 deg, planform area=121.5 in², mac at 234 in from nose
Tails: 3 sets, chord=4.5 in, span=9 in, sweep=10 deg, planform area=243 in², mac at 333 in from nose

### Flight Conditions

Altitude=92 kft (given), Mach number=9 (given)

### The Generative AI System Determines (L/D) MAX Occurs at 13° Angle-of-Attack for:

Maximum range=500 nmi=926 km.

The reference https://en.wikipedia.org/wiki/3M22_Zircon provides a range of 540 nmi. The article mentions development of new fuels, and some internet sources even claim the range of missile can reach 1,000-2,000 km.

| Fuel | h_{PR} (BTU/lbm) | Range (nmi) | Range (km) |
|---|---|---|---|
| RJ-5 | 17,900 | 500 | 926 |
| Hydrocarbon | 19,000 | 528 | 978 |
| | 25,000 | 681 | 1261 |
| | 30,000 | 804 | 1489 |
| | 35,000 | 925 | 1713 |
| | 40,000 | 1,041 | 1928 |
| | 45,000 | 1155 | 2139 |
| Hydrogen | 51,600 | 1301 | 2409 |

Artificial intelligence and machine learning are good at classification problems. In a multi-sensor, multi-intelligence (“multi-INT”) environment, the need to assimilate and assess results from many collectors simultaneously typically falls to a human. In the theater of battle, adversaries often switch to reserved modes for radar, telemetry, and communications. Systems that are built using traditional machine learning techniques to classify these signals are unable to classify signals in the wild until a human has identified and labelled enough copies. In a joint multi-INT environment, not all targets will be detected by all collectors. This results in sparse data from any single collector. Similarly, the entire battlespace may not be evenly surveyed by all collection assets, meaning the collection network itself is sparse. A challenge is fusing never-before-seen information, from a sparse network, in a timely fashion that can render predictive and prescriptive action in the battlespace in real time. This requires techniques and processes that push processing further to the edge, and that can “self-train” autonomously on data as it is presented.

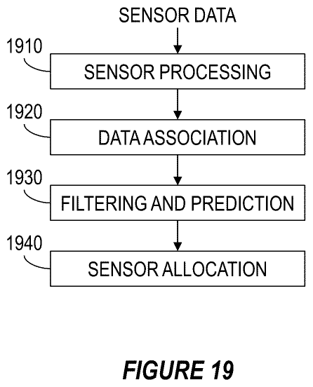

FIG. 19 illustrates a flow chart of a method or process to develop a design of a system. In this case, the method or process is linking sensors and shooters through a high-speed network powered by a generative AI system. In response to receiving sensor data (stored in memory), the generative AI system processes the sensor data. The sensor processing 1910 (on a processor) is used for multi-sensor tracking and data fusion for improved target information, elimination of false alarms, reduced susceptibility to countermeasures, and enabling faster decision-making. (See, e.g., U.S. patent application Ser. Nos. 18/050,661 and 16/674,942, referred to as “evolved AI”.) Following the sensor processing 1910, the generative AI system performs data association 1920 (on a processor). The data association 1920 is used to partition sensor data by source, form tracks, estimate the number of targets, and characterize and classify targets by their intent. (See, e.g., U.S. patent application Ser. No. 18/475,963.)

Following the data association 1920, the generative AI system performs filtering and prediction 1930 (on a processor) of the data. The filtering and prediction 1930 is used to estimate track state (range, range rate, elevation, azimuth) by passive means (preferably) or actively-aided in a sporadic way. (See, e.g., U.S. patent application Ser. No. 18/187,860.) Following the filtering and prediction 1930, the generative AI system performs sensor allocation 1940 (via a processor). The sensor allocation 1940 is used to optimize the allocation of multiple sensors to multiple targets. (See, e.g., U.S. patent application Ser. No. 18/050,661.)

An example embodiment of how this aggregation may be implemented is set forth below. In the battlespace, when a novel signal is detected, evolved AI can rapidly form a matched filter and distribute the signature to other collectors. Any in-phase and quadrature component (“IQ”) stream can act as an input for the filter. The filter should be signal-to-noise ratio (“SNR”) and sample rate agnostic. This automates the formation and distribution of matched filters for novel signals. The filters may be compound and consist of a sequence of pulses. Thus, the matched filter strategy should support a compound signal definition.

This same technique can be used to parameterize new signal types. Stochastic matched filters provide a mechanism to extract parameters about a signal without performing fast Fourier transforms (“FFTs”). The outputs are stochastic parameter extracted evolved AI descriptor words (“SPEEDWs”). These parameters form a highly compressed description of a signal. Combined with unsupervised clustering, the parameterization of a cluster can be used to send a highly compact data stream about the signal environment. This can be exploited from multiple sensors, and aid in developing a common operating picture of the battlespace.

One method to identify novel signals is unsupervised clustering. Unsupervised clustering with dynamic unsupervised clustering by algorithmic triangulation (“DUCAT”) provides a mechanism to group signals and filter out noise. DUCAT takes normalized inputs from multiple sensors such as pulse descriptor words (“PDWs”) or SPEEDWs. DUCAT provides an application programming interface (“API”) compliant replacement for hierarchical density-based spatial clustering of applications with noise (“HDBSCAN”), but includes memory of previous clusters.

Additional metadata provided by collectors such as angle-of-arrival (“AoA”), collector position metadata, or area-of-interest (“AoI”), can be used to provide automated collection targeting based on the outputs from DUCAT. In a multi-beam collection aperture, search beams can continuously operate, but control of targeting beams can be directed by evolved AI.

Unsupervised clustering experiments have demonstrated that only three parameters are needed to form clusters, but multiple sensors provide additional and diverse metadata for the collections. DUCAT can be used to fuse this data. Any elements matching on the minimal set are instantly grouped together. A second pass of a group can aggregate all the metadata to form a full picture of the signal (the blind men and the elephant).

IQ data is expensive to ship around, but sensors with modest bandwidth can run a detector, and only ship out compact data streams, such as only detects. If they buffer data locally, the DUCAT unsupervised clustering algorithm could request a “sample” of the data as needed for deeper investigation (herd medicine). Sampled elements from the cluster can be sent for additional IQ specialized processing.

Utilizing a vigorous AI approach (see, e.g., U.S. patent application Ser. Nos. 16/675,000 and 18/449,532), a supervisor AI can collect normalized compact results from multiple sensors. This is used to cross-target between multiple sensors, such as those in a swarm. In lieu of multiple beams being redirected for search or interrogation, different sensors in a swarm or cluster can be re-tasked in a similar fashion. Vigorous AI can be used whether tracking is at the sensor-level (where each sensor forms its own track and then combined with other tracks) or at the central-level (where sensor data is combined first, then tracks are formed).

Joint all domain command and control (“JADC2”) includes data fusion from different “INTs.” In the context of signal intelligence (“SIGINT”), we have shown fusion from different collectors, but all from SIGINT. Tips from other sources of intelligence, such as geographic intelligence (“GEOINT”), foreign instrumentation signals intelligence (“FISINT”), or human intelligence (“HUMINT”), provide metadata about activities that can be used by the vigorous AI suite to reduce search areas, or create focused interrogation areas of the geography or spectrum.

Invoking an intelligent predictor, track data (angle-only measurements and triangulation) may be filtered to obtain better state estimates (range, range rate, angular elevation, and azimuth) to identify target type and intent with confidence levels, preferentially using a passive system, but no more than an aided, sporadic active system. Finally, sensor allocation is determined by adaptively directing multisensory systems to search for new targets, update target positions, identify targets, and remain covert/evade detection.

In addition, the generative AI system may be utilized to determine the optimal allocation of multiple sensors to multiple targets based on the state of each sensor/target, the target's identification, and threat level, among other characteristics. All these techniques combine to form an autonomous detection and prosecution system. The system observes through stochastic parameter extraction and matched filter detection. The system orients unsupervised clustering from individual sensors, unsupervised clustering across sensors, multi-pass, selective deep processing of subsets of the cluster, and compact data formats sent back to omnivisor. An omnivisor is an “all-seeing supervisor” that monitors AI/ML concurrent processes, and subsequently constructs a collaborative weighted performance metric from their results. The system makes decisions via omnivisor, and acts (prescribes) by sending notifications to higher authority such as personnel, directs additional collection from new sensors, and redirects sensor beams.

Regarding sensor processing, the purpose of sensor fusion is to combine sensor benefits to obtain improved target information, eliminate false alarms, reduce susceptibility to countermeasures, and enable faster decision-making. Typical sensor pairings for increased benefits include microwave and laser sensors. This combination allows for a broad search area in angular position and range while offering improved angular position accuracy. Another pairing includes passive infrared searching/tracking and laser sensors. This combination allows large area searching with improved target range. Another pairing includes a thermal imager and laser sensors. This combination provides search and target recognition along with an improved target range. Another pairing includes millimeter wave and thermal imager. This combination delivers short range search combined with target recognition. Another pairing includes microwave and thermal imager sensors. This combination allows for a broad search area in angular position and range while providing target recognition.

It would be beneficial to have an automated way to design individual sensors and combine them to yield optimal value. Conventional systems are unable (in practical terms) to autogenerate an entire new sensor fusion design. With a high-performance non-linear optimization system, and the entire corpus of physical equations (Skolnick's well known Radar Handbook), along with expert system design rules, a hybrid generative AI system as described herein can provide the optimal design. The generative AI system incorporates discontinuous, non-convex, and non-differentiable system equations, heretofore unfeasible on practical computing platforms. The benefits of the systems described herein include improved target information, elimination of false alarms, reduced susceptibility to countermeasures, and enabling faster decision-making. In other words, this generative AI system can autonomously generate, implement and control designs, or can generate assessments of observed designs to control systems-of-systems.

As mentioned above, a desired objective value of a sensor system can be represented by multiple metrics and are context-sensitive to the decision-maker, organization, acquisition process, previous investments, among others. Goal of the design process is to optimize this value. An example of the generative AI system to a sensor system follows.

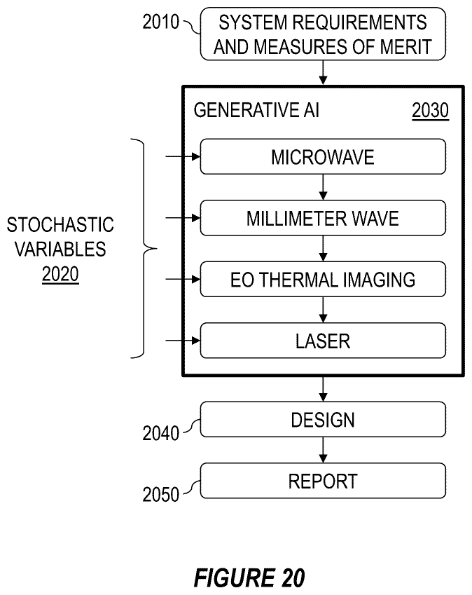

FIG. 20 illustrates a flow chart of a process to develop a design of a system such as a sensor system. In this case, the generative AI system incorporates the measures of merit (e.g., performance requirements) into the system requirements (aggregated system requirements and measures of merit 2010) stored in memory such that they can be met collectively. For microwave sensors, the measures of merit include, without limitation, detection range and/or tracking range. For millimeter wave sensors, the measures of merit include, without limitation, ground clutter and/or rain sensor cross section. For electro-optical thermal imaging sensors, the measure of merit include, without limitation, minimal resolvable temperature. For laser sensors, the measures of merit include, without limitation, heterodyne and/or direct signal-to-noise ratio.

Also, the design parameters for each sensor subsystem (e.g., microwave, millimeter wave, electro-optical thermal imaging, and laser sensors) provided (received and stored in memory) are represented by stochastic (random) variables 2020 as recommended by subject matter experts. The design parameters for microwave and millimeter wave sensors include, without limitation, target cross section, target range, and sensor pulse width. The design parameters for electro-optical thermal imaging, and laser sensors include, without limitation, optical efficiency and detector peak detectivity. In this MBSE/MDO embodiment, the generative AI system 2030 contains (stored in memory) the first-order physics-based engineering (mathematical) equations (relationships, a plant model) of all of the sensor subsystems. When executed on a processor, the generative AI system 2330 produces an advanced (e.g., optimal) design 2040 of individual sensors or multiple sensors for an operation of the sensor system, in aggregate, subject to constraints of size, weight, and power meeting the aggregated system requirements and measures of merit 2010 in a single step (or iteration) improving computational efficiency and reducing power consumption and other resources of the processor operating the generative AI system 2030. Furthermore, (optimal) design parameters (extracted automatically from the stochastic variables 2020) are reported (reported design parameters 2050), including sensitivity analyses of the design parameters, such that the system engineer can immediately identify performance drivers for the design 2040 to control, operate, and/or maintain (maintenance) the sensor system. Of course, a multitude and diversity of domains can be applied to the generative AI system 2030 to produce the design 2040.

Again, the design can be implemented within the context of a complex system of systems to, for instance, control, operate and maintain complex real systems such as vehicle systems (e.g., aerospace vehicle systems) and threat analysis systems to improve the design, monitoring, operation and/or maintenance thereof. Additionally, the generative AI system improves the efficiency and reduces power consumption of the processor and memory operating the generative AI system by reducing the iterations of developing the advanced design. The generative AI system builds a model with a comprehensive set of physics-based engineering equations; populates the model with data, including uncertainty, verifies and validates the model with known baseline systems, implements (controls) the system within the context of a complex system of systems.

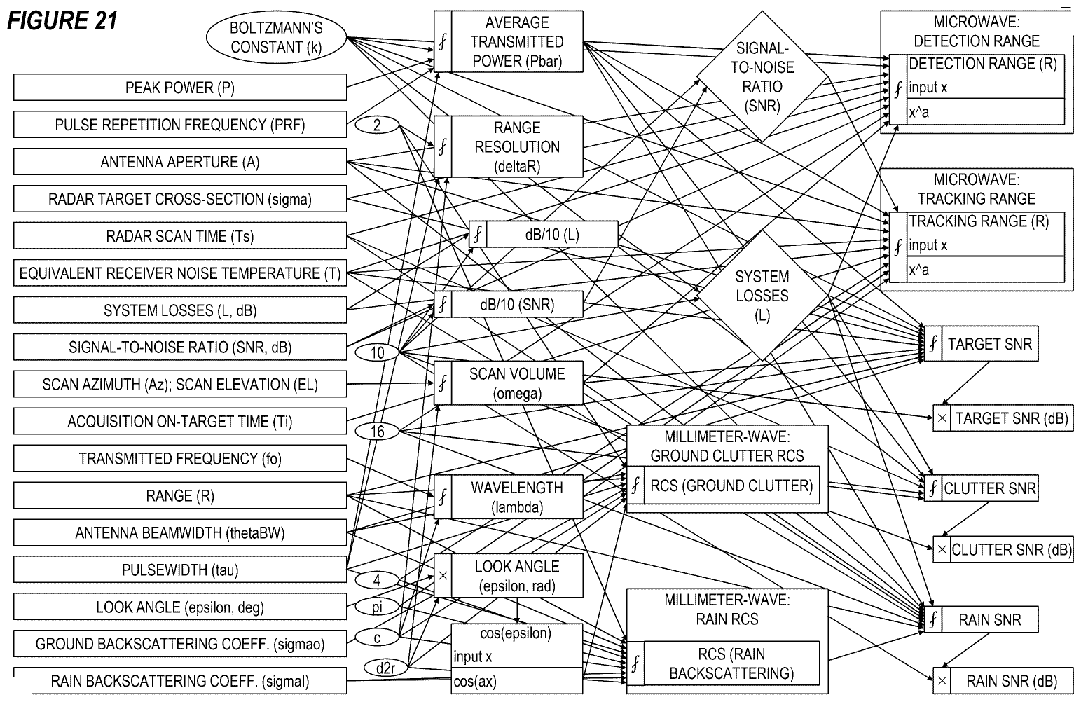

FIG. 21 illustrates a tornado chart of an implementation of the physical equations representing a sensor system (e.g., microwave/millimeter wave sensor system). The desired goal of the generative AI system is to find the design that maximizes range. Several independent design variables are of interest. While sensor maximum detection/tracking range is depicted in the FIGURE as a single dependent variable, the generative AI system comprehends and teaches multivariate descriptions of sensor systems. As detection/tracking range increases, the sensor system gets larger and more complex. Longer range requires more average transmitted power and larger antenna aperture area with less SNR ratio and smaller scan volume. Therefore, generally, development cost increases with range.

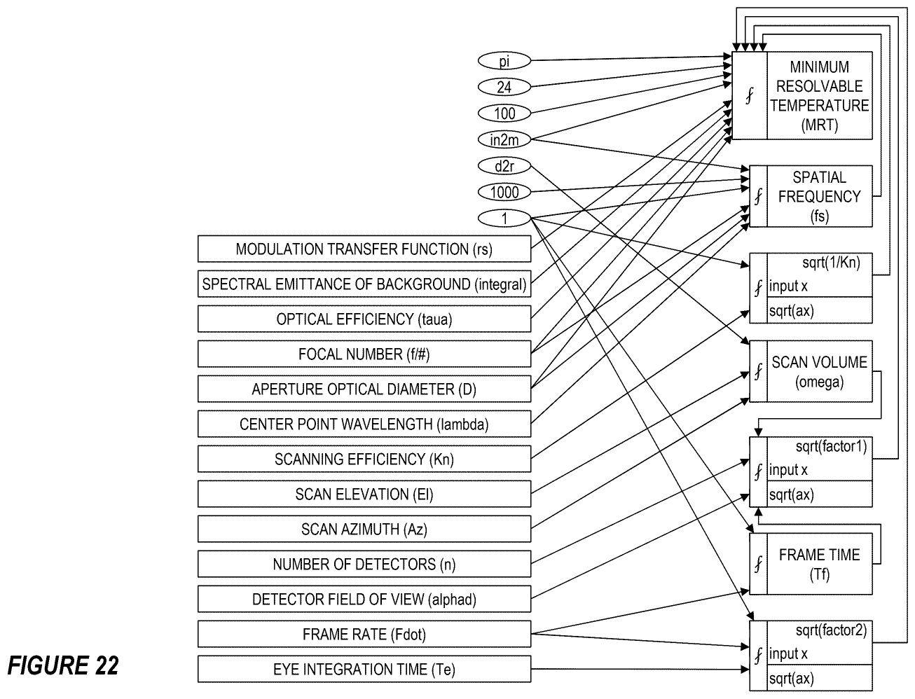

FIG. 22 illustrates a tornado chart of an implementation of the physical equations representing a sensor system (e.g., an electro-optical thermal imaging system). The desired goal of the analysis system is to find the design that minimizes resolvable temperature. Several independent design variables are of interest. While sensor minimum resolvable temperature is depicted in the FIGURE as a single dependent variable, the generative AI system comprehends and teaches multivariate descriptions of sensor systems. As resolvable temperature decreases, the electro-optical thermal imaging system gets larger and more complex. Lower resolvable temperature requires a smaller scan volume, higher optical and scanning efficiencies, larger aperture diameter, and more detectors with a larger field of view. Therefore, generally, development cost increases with lower resolvable temperature.

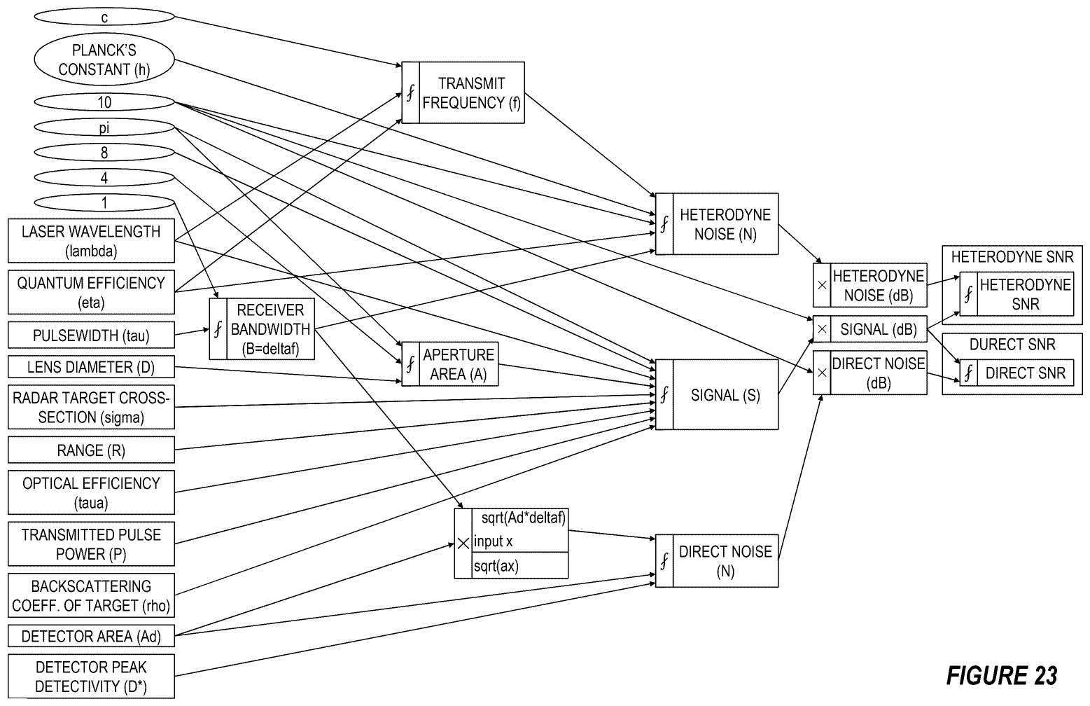

FIG. 23 illustrates a tornado chart of an implementation of the physical equations representing a sensor system (e.g., a laser sensor system). The desired goal of the analysis system is to find the design that maximizes SNR, whether the system is heterodyne or direct. Several independent design variables are of interest. While sensor maximum SNRs are depicted in the FIGURE as single dependent variables (heterodyne SNR and direct SNR), the generative AI system comprehends and teaches multivariate descriptions of sensor systems. As SNR increases, the laser sensor system gets larger and more complex. Longer laser range requires higher signal and lower noise. Higher signal is obtained by increasing the transmitted pulse power, increasing the aperture area, decreasing the bandwidth of the system, and increasing the detectivity (direct) or quantum efficiency (heterodyne). Therefore, generally, development cost increases with range. Optimizing the aggregate sensor system (microwave, millimeter wave, electro-optical thermal imaging, and laser sensors) for an operational scenario is not obvious.

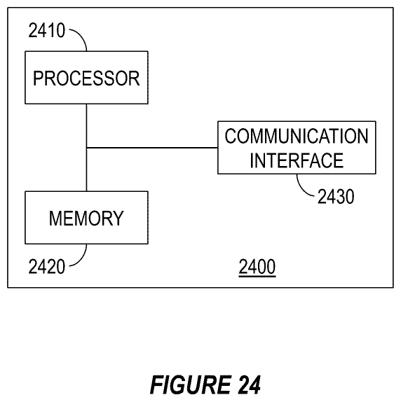

FIG. 24 illustrates a block diagram of an embodiment of an apparatus 2400 for operating a generative AI system. The apparatus 2400 is configured to perform functions described hereinabove for the generative AI system. The apparatus 2400 includes a processor (or processing circuitry) 2410, a memory 2420 and a communication interface 2430 such as a graphical user interface. The apparatus operates the generative AI system to create models and processes to control, operate and maintain complex real systems such as vehicle systems (e.g., aerospace vehicle systems), threat analysis systems and sensor systems to improve the design, monitoring, operation and maintenance thereof.

The functionality of the apparatus 2400 may be provided by the processor 2410 executing instructions stored on a computer-readable medium, such as the memory 2420 shown in FIG. 24. Alternative embodiments of the apparatus 2400 may include additional components (such as the interfaces, devices and circuits) beyond those shown in FIG. 24 that may be responsible for providing certain aspects of the device's functionality, including any of the functionality to support the solution described herein.

The processor 2410 (or processors), which may be implemented with one or a plurality of processing devices, perform functions associated with its operation including, without limitation, performing the operations of the generative AI system. The processor 2410 may be of any type suitable to the local application environment, and may include one or more of general-purpose computers, special purpose computers, microprocessors, digital signal processors (“DSPs”), field-programmable gate arrays (“FPGAs”), application-specific integrated circuits (“ASICs”), and processors based on a multi-core processor architecture, as non-limiting examples.

The processor 2410 may include, without limitation, application processing circuitry. In some embodiments, the application processing circuitry may be on separate chipsets. In alternative embodiments, part or all of the application processing circuitry may be combined into one chipset, and other application circuitry may be on a separate chipset. In still alternative embodiments, part or all of the application processing circuitry may be on the same chipset, and other application processing circuitry may be on a separate chipset. In yet other alternative embodiments, part or all of the application processing circuitry may be combined in the same chipset.

The memory 2420 (or memories) may be one or more memories and of any type suitable to the local application environment, and may be implemented using any suitable volatile or nonvolatile data storage technology such as a semiconductor-based memory device, a magnetic memory device and system, an optical memory device and system, fixed memory and removable memory. The programs stored in the memory 2420 may include program instructions or computer program code that, when executed by an associated processor, enable the respective device 2400 to perform its intended tasks. Of course, the memory 2420 may form a data buffer for data transmitted to and from the same. Exemplary embodiments of the system, subsystems, and modules as described herein may be implemented, at least in part, by computer software executable by the processor 2410, or by hardware, or by combinations thereof.

The communication interface 2430 modulates information for transmission by the respective apparatus 2400 to another apparatus. The respective communication interface 2430 is also configured to receive information from another processor for further processing. The communication interface 2430 can support duplex operation for the respective other processor 2410.

As described above, the exemplary embodiments provide both a method and corresponding apparatus consisting of various modules providing functionality for performing the steps of the method. The modules may be implemented as hardware (embodied in one or more chips including an integrated circuit such as an application specific integrated circuit), or may be implemented as software or firmware for execution by a processor. In particular, in the case of firmware or software, the exemplary embodiments can be provided as a computer program product including a computer readable storage medium embodying computer program code (i.e., software or firmware) thereon for execution by the computer processor. The computer readable storage medium may be non-transitory (e.g., magnetic disks; optical disks; read only memory; flash memory devices; phase-change memory) or transitory (e.g., electrical, optical, acoustical or other forms of propagated signals-such as carrier waves, infrared signals, digital signals, etc.). The coupling of a processor and other components is typically through one or more busses or bridges (also termed bus controllers). The storage device and signals carrying digital traffic respectively represent one or more non-transitory or transitory computer readable storage medium. Thus, the storage device of a given electronic device typically stores code and/or data for execution on the set of one or more processors of that electronic device such as a controller.

Although the embodiments and its advantages have been described in detail, it should be understood that various changes, substitutions, and alterations can be made herein without departing from the spirit and scope thereof as defined by the appended claims. For example, many of the features and functions discussed above can be implemented in software, hardware, or firmware, or a combination thereof. Also, many of the features, functions, and steps of operating the same may be reordered, omitted, added, etc., and still fall within the broad scope of the various embodiments.

Moreover, the scope of the various embodiments is not intended to be limited to the embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized as well. Accordingly, the appended claims are intended to include within their scope such processes, machines, manufacture, compositions of matter, means, methods, or steps.

1. A method of operating a generative artificial intelligence system on a processor and memory, comprising:
incorporating measures of merit into system requirements for an aerospace vehicle system to provide aggregated system requirements and measures of merit;
receiving design parameters of said aerospace vehicle system represented as stochastic variables; and
executing first order physics-based engineering equations of said design parameters with said generative artificial intelligence system on said processor to produce a design for an operation of said aerospace vehicle system to meet said aggregated system requirements and measures of merit in a single iteration improving computational efficiency and reducing power consumption of said processor operating said generative artificial intelligence system.

2. The method as recited in claim 1 wherein said executing first order physics-based engineering equations includes modulating said design parameters until a multi-dimensional combination thereof arrives at said design that optimizes said measures of merit of said aggregated system requirements and measures of merit for said aerospace vehicle system.

3. The method as recited in claim 1 wherein said design parameters include aerodynamics parameters, propulsion parameters, weight parameters and trajectory parameters of said aerospace vehicle system.

4. The method as recited in claim 1 wherein said measures of merit include survivability, cost, reliability and/or safety of said aerospace vehicle system.

5. The method as recited in claim 1 further comprising providing reported design parameters extracted automatically from said stochastic variables including a sensitivity analysis for said design parameters to identify performance drivers for said design of said aerospace vehicle system.

6. The method as recited in claim 1 wherein said first order physics-based engineering equations are discontinuous, non-convex, and non-differentiable system equations.

7. The method as recited in claim 1 wherein said first order physics-based engineering equations include interdependencies between said design parameters and an overall impact on said aggregated system requirements and measures of merit for said aerospace vehicle system.

8. The method as recited in claim 1 wherein said stochastic variables include stochastic ranges of said design parameters.

9. A generative artificial intelligence system operative on a processor and memory configured to:
incorporate measures of merit into system requirements for an aerospace vehicle system to provide aggregated system requirements and measures of merit;
receive design parameters of said aerospace vehicle system represented as stochastic variables; and
execute first order physics-based engineering equations of said design parameters with said generative artificial intelligence system on said processor to produce a design for an operation of said aerospace vehicle system to meet said aggregated system requirements and measures of merit in a single iteration improving computational efficiency and reducing power consumption of said processor operating said generative artificial intelligence system.

10. The generative artificial intelligence system as recited in claim 9 wherein said generative artificial intelligence system is configured to modulate said design parameters until a multi-dimensional combination thereof arrives at said design that optimizes said measures of merit of said aggregated system requirements and measures of merit for said aerospace vehicle system.

11. The generative artificial intelligence system as recited in claim 9 wherein said design parameters include aerodynamics parameters, propulsion parameters, weight parameters and trajectory parameters of said aerospace vehicle system.

12. The generative artificial intelligence system as recited in claim 9 wherein said measures of merit include survivability, cost, reliability and/or safety of said aerospace vehicle system.

13. The generative artificial intelligence system as recited in claim 9 wherein said generative artificial intelligence system is configured to provide reported design parameters extracted automatically from said stochastic variables including a sensitivity analysis for said design parameters to identify performance drivers for said design of said aerospace vehicle system.

14. The generative artificial intelligence system as recited in claim 9 wherein said first order physics-based engineering equations include interdependencies between said design parameters and an overall impact on said aggregated system requirements and measures of merit for said aerospace vehicle system.

15. A computer program product comprising program code stored in a non-transitory computer readable medium operable on a computer with a processor and memory for executing a generative artificial intelligence system and configured to:
incorporate measures of merit into system requirements for an aerospace vehicle system to provide aggregated system requirements and measures of merit;
receive design parameters of said aerospace vehicle system represented as stochastic variables; and
execute first order physics-based engineering equations of said design parameters with said generative artificial intelligence system on said processor to produce a design for an operation of said aerospace vehicle system to meet said aggregated system requirements and measures of merit in a single iteration improving computational efficiency and reducing power consumption of said processor operating said generative artificial intelligence system.

16. The computer program product as recited in claim 15 wherein said computer program product for executing said generative artificial intelligence system is configured to modulate said design parameters until a multi-dimensional combination thereof arrives at said design that optimizes said measures of merit of said aggregated system requirements and measures of merit for said aerospace vehicle system.

17. The computer program product as recited in claim 15 wherein said design parameters include aerodynamics parameters, propulsion parameters, weight parameters and trajectory parameters of said aerospace vehicle system.

18. The computer program product as recited in claim 15 wherein said measures of merit include survivability, cost, reliability and/or safety of said aerospace vehicle system.

19. The computer program product as recited in claim 15 wherein said computer program product for executing said generative artificial intelligence system is configured to provide reported design parameters extracted automatically from said stochastic variables including a sensitivity analysis for said design parameters to identify performance drivers for said design of said aerospace vehicle system.

20. The computer program product as recited in claim 15 wherein said first order physics-based engineering equations include interdependencies between said design parameters and an overall impact on said aggregated system requirements and measures of merit for said aerospace vehicle system.
